(19) United States
(12) Patent Application Publication
(10) Pub. No.: US 2025/0173560 A1
(43) Pub. Date: May 29, 2025

(54) ADAPTING ION IMPLANT MODEL DURING MAINTENANCE RECOVERY

(71) Applicant: Applied Materials, Inc., Santa Clara, CA (US)

(72) Inventor: Richard Allen SPRENKLE, South Hamilton, MA (US)

(73) Assignee: Applied Materials, Inc., Santa Clara, CA (US)

(21) Appl. No.: 18/520,309

(22) Filed: Nov. 27, 2023

(51) Int. Cl. G06N 3/08

(52) U.S. Cl. CPC G06N 3/08

(57) ABSTRACT

Techniques to adapt an ion implant model during maintenance recovery are described. A method includes receiving setting parameters for an ion implanter, the setting parameters includes a set of control parameters corresponding to a set of process parameters for the ion implanter, predicting a preventative maintenance (PM) recovery time for a PM recovery phase of the ion implanter based on the setting parameters, the PM recovery time representing a time interval between a start time of the PM recovery phase and an end time of the PM recovery phase, using a machine learning model, and presenting the recovery time on a graphical user interface (GUI) of an electronic device. Other embodiments are described and claimed.

### BACKGROUND

An ion implanter is a device used in the semiconductor industry for doping or modifying the properties of materials. It is specifically designed to precisely introduce impurities, known as dopants, into target material to create semiconductor devices like transistors. The target material is usually a silicon wafer. The process involves accelerating ions to high speeds using an electric field and directing them towards the target material. The accelerated ions penetrate a substrate of the target material, displacing atoms and creating a controlled distribution of dopants in the substrate. The ion implanter typically comprises various components, such as an ion source to generate the desired ions, an accelerator to increase their energy, a mass analyzer to select the desired ions, and a beamline system to direct and focus the ion beam onto the substrate. The implanter settings, such as energy and current, are carefully controlled to achieve the desired dopant depth and concentration profiles. By precisely controlling the ion energy and dose, an ion implanter allows the customization of material properties. It plays a crucial role in the fabrication of integrated circuits, where different dopants create various regions necessary for device functionality, such as transistor gates, source, and drain regions. Overall, an ion implanter is a vital tool in the semiconductor industry for precisely introducing controlled impurities into materials, enabling the creation of advanced electronic devices.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates an ion implanter in accordance with one embodiment.

FIG. 2 illustrates an ion implanter in accordance with one embodiment.

FIG. 3 illustrates an inferencing system in accordance with one embodiment.

FIG. 4 illustrates a logic flow in accordance with one embodiment.

FIG. 5 illustrates a logic flow in accordance with one embodiment.

FIG. 6 illustrates a machine learning model in accordance with one embodiment.

FIG. 7 illustrates an artificial neural network in accordance with one embodiment.

FIG. 8 illustrates an artificial neural network in accordance with one embodiment.

FIG. 9 illustrates an artificial neural network in accordance with one embodiment.

FIG. 10 illustrates a timing diagram in accordance with one embodiment.

FIG. 11 illustrates a logic flow in accordance with one embodiment.

FIG. 12 illustrates a training device in accordance with one embodiment.

FIG. 13 illustrates a training system in accordance with one embodiment.

FIG. 14 illustrates computer readable medium (CRM) in accordance with one embodiment.

FIG. 15 illustrates a computing system in accordance with one embodiment.

### DETAILED DESCRIPTION

Embodiments are generally directed to artificial intelligence (AI) and machine learning (ML) techniques for controlling a configuration or operation of an ion implanter. Some embodiments are particularly directed to AI and ML techniques to assist in automatically predicting preventative maintenance (PM) phase cycles and operational phase cycles for an ion implanter. For example, embodiments are designed to predict a start time for a PM phase cycle, an end time for a PM phase cycle, and a recovery time for the ion implanter between the start time and the end time. In another example, some embodiments are designed to predict a start time for an operational phase cycle, an end time for the operational phase cycle, and an operational time between the start time and end time. The use of ML models to more accurately predict PM phase cycles and operational phase cycles for an ion implanter leads to more efficient and effective use of the ion implanter, which is a relatively expensive tool in a semiconductor fabrication facility designed to produce semiconductor wafers.

By way of background, an ion implanter typically undergoes a PM at certain planned time intervals based on a defined PM schedule. These time intervals are sometimes referred to as a PM cycle or PM phase (hereinafter referred to as a “PM phase”). In the context of an ion implanter, a PM phase refers to a planned and routine maintenance activity aimed at preventing equipment breakdowns or failures. It is a proactive approach to maintenance that focuses on regularly inspecting, servicing, and replacing components or parts before they become problematic. During the preventative maintenance phase, specific tasks may include: (1) visual or automated inspections to identify signs of wear, damage, or malfunctions; (2) applying appropriate lubricants to moving parts to reduce friction and prevent premature wear; (3) removing dust, debris, or contaminants from critical components and internal systems; (4) checking and adjusting equipment settings to ensure accurate performance and measurement; (5) scheduled replacement of worn-out parts, such as belts, filters, sensors, or bearings; (6) performing tests or diagnostic procedures to verify proper functionality and performance; or (7) maintaining detailed records of maintenance activities, including performed tasks, dates, and results. By regularly conducting preventative maintenance, potential issues or equipment failures can be identified and addressed before they cause significant disruptions or downtime. This proactive approach helps increase equipment reliability, extend its lifespan, optimize performance, and reduce the likelihood of costly breakdowns. It is important to follow manufacturer guidelines and industry best practices for timing and specific maintenance procedures during the preventative maintenance phase to ensure optimal equipment operation and minimize risks.

Once a PM is performed on an ion implanter, there exists a recovery time for the newly configured ion implanter before it becomes fully operational again. The recovery time spans a time interval defined between a start time after the PM is performed (post-PM) and an end time when the ion implanter is fully operational and delivering consistent ion beams with required specifications as measured by output metrology. Typically, the recovery time after a PM is estimated based on a set of heuristics. Heuristics are often used when an optimal solution is difficult to determine or too computationally expensive to find. Although heuristics may not guarantee an optimal solution, they can be effective in achieving satisfactory results in many real-world scenarios. An operator may use heuristics to estimate a recovery time based on historical information. For example, a PM recovery time for an ion implanter normally takes 6 to 24 hours depending on a particular configuration or setup (e.g., a recipe). If a particular recipe for an ion implanter normally takes 8 hours, the operator may estimate a PM recovery time of 10 hours to be safe.

Using heuristics to estimated PM recovery time, however, may lead to several challenges. For example, if the estimated PM recovery time is too long, this means that the ion implanter will be unavailable for production or manufacturing tasks during that period. This can result in reduced productivity and potentially cause delays in meeting production schedules. Further, recovery time directly affects the rate at which wafers or substrates can be processed. If the ion implanter takes longer to recover, the throughput or the number of units processed per unit of time may decrease. This can impact overall production efficiency and output. Extended recovery time can also lead to increased costs due to the underutilization of the ion implanter during the downtime. Higher operational costs may be incurred if the extended recovery affects production targets and requires additional resources to compensate for the lost time. In addition, the ion implanter is a critical step in the manufacturing process, and therefore delays in its recovery can ripple down the production line and affect overall manufacturing timelines. This can potentially disrupt supply chain commitments and customer delivery schedules.

Underestimating PM recovery time may also lead to inefficient use of testing resources to confirm a PM recovery end time when the ion implanter is fully operational. Typically, an operator estimates a PM recovery time, and performs tests to determine whether a PM endpoint has actually been reached. One test is performed using a testing wafer, sometimes referred to as a re-qualification wafer, to test performance of the ion implanter. The testing wafer is a relatively expensive and scarce resource. Consequently, inaccurate estimates of PM recovery times may lead to an unnecessary waste of testing wafers in a trial-by-error attempt to determine a PM recovery end time.

Embodiments solve these and other technical challenges. After a PM is performed for an ion implanter, embodiments utilize a ML model that receives as input setting parameters for components of the ion implanter, where the setting parameters include a set of control parameters and/or a set of process parameters corresponding to the control parameters. The setting parameters may collectively represent, for example, a recipe for the ion implanter. The ML model then automatically predicts, suggests or estimates a recovery time for the ion implanter post-PM that is more precise relative to prior heuristic solutions. In this manner, an operator of the ion implanter will be able to appropriately plan PM phases for the ion implanter to minimize downtime and associated costs.

Specifically, after a PM is performed on an ion implanter, the newly configured ion implanter may experience deviation from steady state behavior. These deviations are characterized as fixed behavior or transitory behavior. Fixed behavior refers to permanent changes or deviations that will remain relatively fixed during the entire PM to the next PM cycle. Examples of fixed behavior include slight changes in alignment or calibration of the ion implanter. Transitory behavior refers to temporary changes or deviations that should only exist during a PM recovery phase and are expected to reduce or disappear once the ion implanter reaches steady state behavior. Examples of transitory behavior includes variable behavior of the ion implanter as it performs outgas, heats up to remove moisture, builds new coatings during recovery, and so forth. Embodiments segment these different types of behaviors of the ion implanter after a PM into either fixed behaviors or transitory behaviors, and then maps the transitory behaviors to a learned variance model to provide quantitative PM endpoint detection. In addition, the learned variance model can track slower transitory changes that occur from a PM endpoint to a next PM cycle in a way that can be leveraged to both estimate the next PM due as well account for wear or stress of the ion implanter over time.

In one embodiment, for example, transfer learning techniques are used to adapt a control model during maintenance recovery to form a variance model designed to predict PM phase cycles for an ion implanter. Transfer learning is a technique in machine learning where knowledge gained from one task is leveraged to help improve the performance of a related but different task. Instead of starting the learning process from scratch for the new task, transfer learning allows us to transfer the knowledge or features learned from a pre-trained model to a new model, thus saving computational resources and time. In transfer learning, the pre-trained model is typically trained on a large dataset. By utilizing the pre-trained model, the new model can benefit from the general patterns, representations, and knowledge learned from the pre-training task. This transfer of knowledge allows the new model to start with a higher level of performance, especially when the new task involves a smaller dataset. The process typically involves modifying or removing the last few layers (or all layers) of the pre-trained model and replacing them with new layers, which are then trained on the specific task or dataset at hand. This way, the lower-level features learned by the pre-trained model can be preserved, while the higher-level features can be fine-tuned or re-learned to fit the new task.

Embodiments generate a variance model from a control model trained on a training dataset comprising millions of data points. The trained control model performs inferencing operations by receiving a set of control parameters as input, and it infers, suggests or predicts a set of process parameters that correspond to the control parameters as output. The control parameters correspond to hardware and/or software configuration settings for one or more components of an ion implanter. The process parameters correspond to metrics or metrology to measure operations of the ion implanter. The control parameters and corresponding process parameters form a “recipe” used by the ion implanter to generate an ion beam to implant ions into a substrate of a semiconductor wafer.

Embodiments apply transfer learning techniques to the trained or pre-trained control model to form the variance model. In one embodiment, for example, the control model is implemented as an artificial neural network (ANN). Embodiments apply transfer learning techniques to the control model by locking one or more hidden layers of the ANN, while leaving an input layer and an output layer of the ANN unlocked. The unlocked input and output layers are subsequently trained using training data collected during a PM recovery phase for the ion implanter after a PM is performed and during an operational time of the ion implanter until a next or subsequent PM event. The result is a trained variance model capable of performing inferencing operations to predict PM phase cycles for one or more recipes of the ion implanter.

More particularly, embodiments train the control model with training data from multiple recipes across many different types of tools. In one embodiment, for example, the training data covers approximately 200 years of collected data per tool type using 100 signals per tool which amounts to approximately 6-7 billion training vectors, where each training vector is 100 points. The trained control model is used as a basis to train the variance model using transfer learning. The transfer learning leverages the larger set of training data used to train the control model while using far less training data points to re-train the control model as a variance model.

The variance model begins as a copy of the control model. The variance model is trained to learn from training data comprising strategic observations made during a PM recovery phase. Rather than retraining the entire copy of the control model, the variance model (e.g., the copy of the control model) only allows the innermost and outermost neural network layers of the ANN to learn while the hidden layers are locked or frozen. This allows the variance model to capture the major impactors expected during recovery of the ion implanter, such as calibration, moisture, vacuum, and so forth. Embodiments compare predictions made by the variance model to predictions made by the original control model to identify variations or differences, sometimes referred to as “residuals.” Embodiments analyze the residuals to identify fixed behavior versus transitory behavior as a way to determine whether the residuals are new fixed calibration offsets, or alternatively, suitable for positioning on a recovery curve (or wear curve) during operation of the ion implanter. In the latter case, a recovery curve can be built by examining a residual delta between a predicted metrology and actual measured metrology of the ion implanter. The recovery curve can be used to predict a PM recovery time endpoint.

In addition to transitory behaviors caused by a new configuration of the ion implanter after a PM, transitory behaviors of the ion implanter may also be caused by stress or wear of the components of the ion implanter over time, such as during extended periods of operation or multiple PM cycles. For example, an ion implanter may experience wear such as a buildup or erosion of materials on source exit, extraction electrodes, interior surfaces, and so forth. This type of wear will impact all recipes but in different ways.

Embodiments implement a ML model, referred to as a stress model, to model wear of components of the ion implanter. Instead of trying to model “wear” by itself, embodiments use the same set of data used to train the control model to retrain a copy of the control model to form the variance model. In addition, the first and last layer of weights and biases are updated using tagged wear vectors. Variations in these inner and outer layers are captured as the output vector that gets learned along with the input wear vector. Embodiments use residual deltas in the control model to continue to relearn a set of observations per time increment (e.g., each hour during recovery), and evaluate the residuals to the control model to predicted residuals to a PM stress vector.

This approach provides several technical advantages relative to conventional solutions. For example, this approach is both more generalized using a factory PM stress model, but can also be made specific to a customer since it can allow the PM stress model to learn across one or more tools at customer sites where the PM practices are likely different from a factory setting, but consistent within the fabrication plant. This provides several benefits, such as faster recipe changes, less tuning optimization during a long recipe run, tighter process control and statistical process control (SPC) limit validation, PM endpoint detection, and predictions when constant metrology cannot be maintained and a PM will be needed.

The present disclosure will now be described with reference to the attached drawing figures, wherein like reference numerals are used to refer to like elements throughout, and wherein the illustrated structures and devices are not necessarily drawn to scale. As utilized herein, terms “component,” “system,” “interface,” and the like are intended to refer to a computer-related entity, hardware, software (e.g., in execution), and/or firmware. For example, a component can be a processor (e.g., a microprocessor, a controller, or other processing device), a process running on a processor, a controller, an object, an executable, a program, a storage device, a computer, a tablet PC and/or a user equipment (e.g., mobile phone, etc.) with a processing device. By way of illustration, an application running on a server and the server can also be a component. One or more components can reside within a process, and a component can be localized on one computer and/or distributed between two or more computers. A set of elements or a set of other components can be described herein, in which the term “set” can be interpreted as “one or more.”

Further, these components can execute from various computer readable storage media having various data structures stored thereon such as with a module, for example. The components can communicate via local and/or remote processes such as in accordance with a signal having one or more data packets (e.g., data from one component interacting with another component in a local system, distributed system, and/or across a network, such as, the Internet, a local area network, a wide area network, or similar network with other systems via the signal).

As another example, a component can be an apparatus with specific functionality provided by mechanical parts operated by electric or electronic circuitry, in which the electric or electronic circuitry can be operated by a software application or a firmware application executed by one or more processors. The one or more processors can be internal or external to the apparatus and can execute at least a part of the software or firmware application. As yet another example, a component can be an apparatus that provides specific functionality through electronic components without mechanical parts; the electronic components can include one or more processors therein to execute software and/or firmware that confer(s), at least in part, the functionality of the electronic components.

Use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form. Furthermore, to the extent that the terms “including”, “includes”, “having”, “has”, “with”, or variants thereof are used in either the detailed description or the claims, such terms are intended to be inclusive in a manner similar to the term “comprising.” Additionally, in situations wherein one or more numbered items are discussed (e.g., a “first X”, a “second X”, etc.), in general the one or more numbered items may be distinct or they may be the same, although in some situations the context may indicate that they are distinct or that they are the same.

As used herein, the term “circuitry” may refer to, be part of, or include a circuit, an integrated circuit (IC), a monolithic IC, a discrete circuit, a hybrid integrated circuit (HIC), an Application Specific Integrated Circuit (ASIC), an electronic circuit, a logic circuit, a microcircuit, a hybrid circuit, a microchip, a chip, a chiplet, a chipset, a multi-chip module (MCM), a semiconductor die, a system on a chip (SoC), a processor (shared, dedicated, or group), a processor circuit, a processing circuit, or associated memory (shared, dedicated, or group) operably coupled to the circuitry that execute one or more software or firmware programs, a combinational logic circuit, or other suitable hardware components that provide the described functionality. In some embodiments, the circuitry may be implemented in, or functions associated with the circuitry may be implemented by, one or more software or firmware modules. In some embodiments, circuitry may include logic, at least partially operable in hardware.

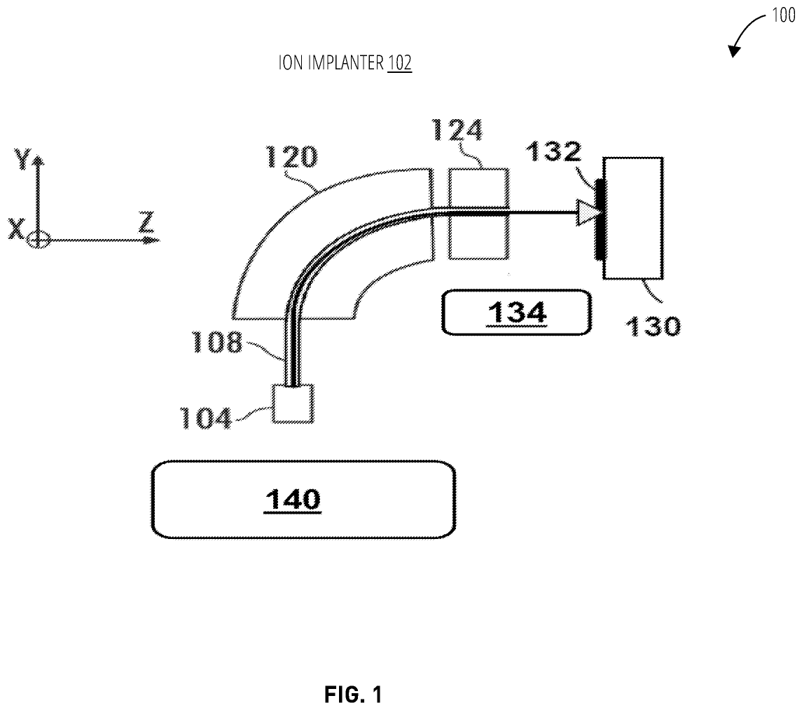

FIG. 1 depicts a schematic view of a system 100 including an ion implanter 102, in accordance with embodiments of the disclosure. The ion implanter 102 may include an ion source 104 for producing an ion beam 108, and a series of beam-line components. The ion source 104 may comprise a chamber for receiving a flow of gas and generating ions. The ion source 104 may also comprise a power source and an extraction electrode assembly (not shown) disposed near the chamber.

Suitable ions for ion beam 108 may include any ion species at a suitable ion energy, including ions such as phosphorous, boron, argon, indium, BF₂, nitrogen, oxygen, hydrogen, inert gas ions, and metallic ions, according to some non-limiting embodiments, with ion energy being tailored according to the exact ion species used.

The beam-line components may include, for example, a mass analyzer 120, and an end station 130, to house and manipulate a substrate 132 that is to intercept the ion beam 108. Thus, the ion source 104, as well as additional beamline components, will provide the ion beam 108 to the substrate 132, having a suitable ion species, ion energy, beam size, and beam angle, among other features, for implanting ions into the substrate 132.

In FIG. 1, in addition to a mass analyzer, according to various non-limiting embodiments, additional components that lie downstream to the ion source 104 may be included. These additional components may include components to accelerate ion beam 108, decelerate ion beam 108, focus ion beam 108, steer ion beam 108, collimate ion beam 108, mass filter ion beam 108, and scan ion beam 108, among other operations. Examples of components to accelerate an ion beam 108 include a DC accelerator column, an RF linear accelerator, and a tandem accelerator, as known in the art. Examples of components to scan the ion beam 108 include an electrostatic scanner or a magnetic scanner. An example of a component to focus the ion beam 108 includes a quadrupole lens.

The ion implanter 102 may further include one or more measurement components, arranged at one or more locations along the beam-line, between ion source 104 and end station 130. For simplicity, these components are shown as beam measurement component 134. Examples of measurement component 134 include ion beam current measurement devices, ion beam angle measurement devices, ion beam energy measurement devices, and ion beam size measurement devices. In one example, the beam measurement component 134 may be a current detector such as a scanning detector, a closed loop current detector, and in particular a closed loop Faraday current detector (CLF), for monitoring beam current provided to the substrate 116. The beam measurement component may be disposed to intercept the ion beam 108 and may be configured to record beam current of the ion beam 108, either at a fixed position, or as a function of position. In some examples, the beam current of ion beam 108 may be measured for a region of interest (ROI), such as the region of the substrate 116.

The ion implanter 102 may also include a control system 140, which system may be included as part of ion implanter 102, to control operations such as adjustments to ion beam parameters. These parameters may include ion beam energy, ion beam size, ion beam current, ion beam angle, and so forth. In turn, the control system 140 may adjust and control these parameters by adjusting the operation of various components of the aforementioned beamline components of the ion implanter 140. The control system 140 may be included in the ion implanter 102 or may be coupled to the ion implanter 102 in order to implement the AI and ML techniques for automatically tuning one or more components of the ion implanter 102 as set forth in the embodiments to follow.

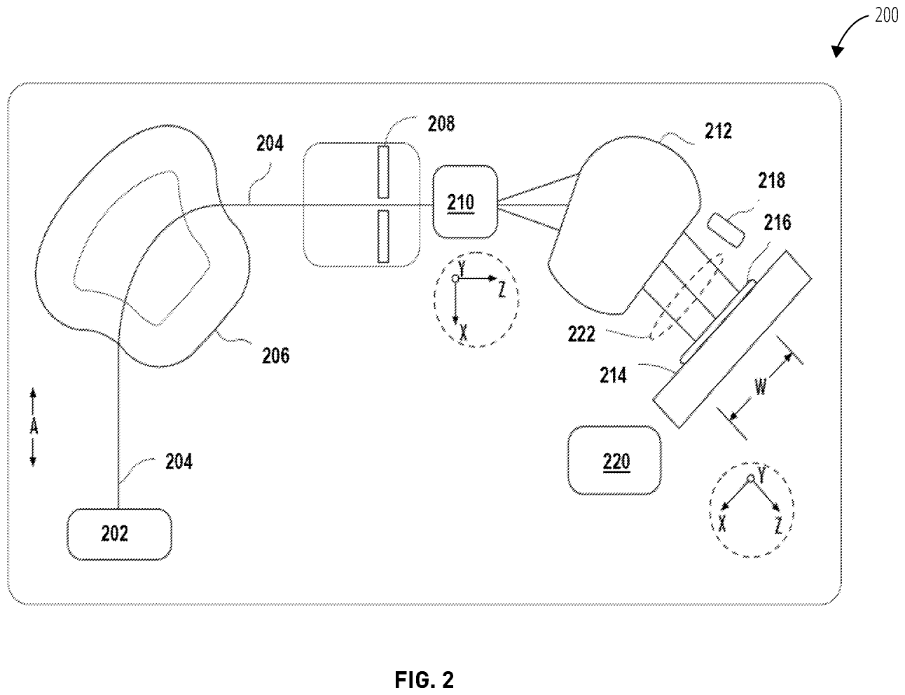

FIG. 2 depicts an ion implanter system 200. The ion implanter system 200 depicts a block form of a beamline ion implanter in accordance with various additional embodiments of the disclosure. The ion implanter system 200 includes an ion source 202 configured to generate an ion beam 204. Suitable ions for ion beam 208 may include any ion species at a suitable ion energy, including ions such as phosphorous, boron, argon, indium, BF₂, nitrogen, oxygen, hydrogen, inert gas ions, and metallic ions, according to some non-limiting embodiments, with ion energy being tailored according to the exact ion species used.

The ion beam 204 may be provided as a spot beam scanned along a direction, such as the X-direction. In the convention used herein, the Z-direction refers to a direction of an axis parallel to the central ray trajectory of an ion beam 204. Thus, the absolute direction of the Z-direction, as well as the X-direction, where the X-direction is perpendicular to the Z-direction, may vary at different points within the ion implanter system 200 as shown. The ion beam 204 may travel through a mass analysis component, shown as analyzer magnet 206, thence through a mass resolving slit 208, and through a collimator 212 before impacting a substrate 216 disposed on a substrate stage 214, which stage may reside within an end station (not separately shown). The substrate stage 214 may be configured to scan the substrate 216 at least along the Y-direction in some embodiments. In some embodiments, the substrate stage 214 may be configured to tilt about the X-axis or Y-axis, so as to change the beam angle of ion beam 204 when impacting substrate 216.

In the example shown in FIG. 2, the ion implanter system 200 includes a beam scanner 210. When the ion beam 204 is provided as a spot beam, the beam scanner 210 may scan the ion beam 204 along the X-direction, producing a scanned ion beam, that enters the collimator 212 and exits in a fashion such that the ion beam 204 impacts the substrate 216 as a scanned ion beam 222 that scanned at the substrate along the X-direction (note the local X-direction in absolute sense may differ at different locations along the beamline as shown). Generally, the ion beam 208 may be scanned back and forth across a substrate 216 for any suitable number of scans, with an accompanying scanning of the substrate 216 in an orthogonal direction to the beam scan direction, until the targeted dose is implanted into substrate 216. The width of the resulting scanned spot beam may be comparable to the width W of the substrate 216 In various embodiments, the ion beam 208 may be scanned at a frequency of several Hz, 10 Hz, 100 Hz, up to several thousand Hz, or greater.

In various non-limiting embodiments, the ion implanter system 200 may be configured to deliver ion beams for “low” energy or “medium” energy ion implantation, such as a voltage range of 1 kV to 300 kV, corresponding to an implant energy range of 1 keV to 300 keV for singly charged ions. As discussed below, the scanning of an ion beam provided to the substrate 116 may be adjusted depending upon calibration measurements before substrate ion implantation using a scanned ion beam. In other embodiments, the ion implanter 200 may be provided with an acceleration component, such as a DC acceleration column, an RF linear accelerator, or a tandem accelerator, where the ion implanter is capable to accelerate the ion beam 208 to energy of 1 MeV, 3 MeV, 5 MeV, or higher energy.

The ion implanter system 200 may further include one or more measurement components, arranged at one or more locations along the beam-line, between ion source 202 and substrate stage 214. For simplicity, these components are shown as beam measurement component 218. Examples of measurement component 218 include ion beam current measurement devices, ion beam angle measurement devices, ion beam energy measurement devices, and ion beam size measurement devices. In one example, the beam measurement component 218 may be a current detector such as a scanning detector, a closed loop current detector, and in particular a closed loop Faraday current detector (CLF), for monitoring beam current provided to the substrate 216. The beam measurement component may be disposed to intercept the ion beam 204 and may be configured to record beam current of the ion beam 204, either at a fixed position, or as a function of position. In some examples, the beam current of ion beam 204 may be measured for a region of interest (ROI), such as the region of the substrate 216.

The ion implanter system 200 may also include a control system 220, which may be included as part of ion implanter system 200, to control operations such as adjustments to ion beam parameters. These parameters may include ion beam energy, ion beam size, ion beam current, ion beam angle, and so forth. In turn, the control system 220 may adjust and control these parameters by adjusting the operation of various components of the aforementioned beamline components of the ion implanter system 200. The control system 220 may be included in the ion implanter system 200 or may be coupled to the ion implanter system 200 in order to implement the AI and ML techniques for automatically tuning one or more components of the ion implanter system 200 as set forth in the embodiments to follow.

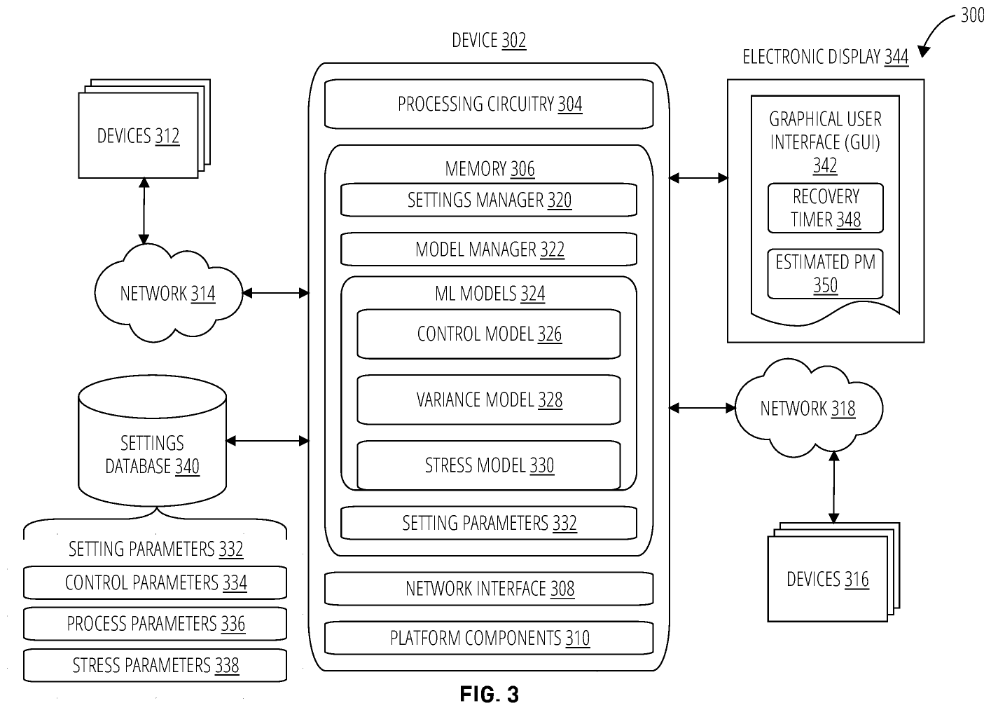

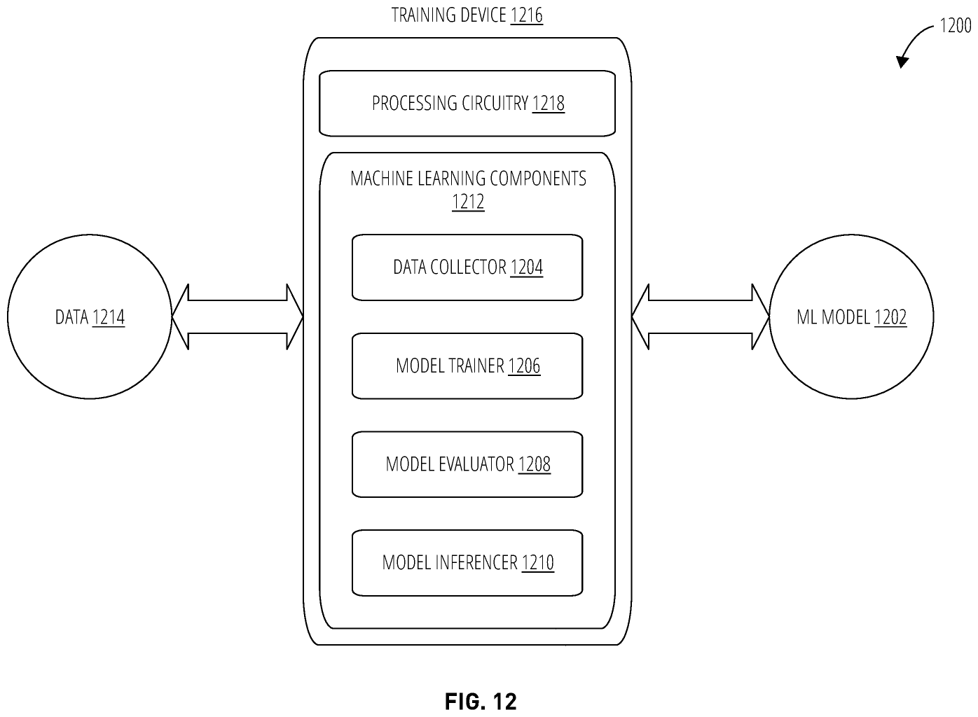

FIG. 3 illustrates an embodiment of an inferencing system 300. The inferencing system 300 may be suitable for implementing one or more embodiments as described herein. In one embodiment, for example, the inferencing system 300 may implement a set of trained ML models 324, including a control model 326, a variance model 328, and a stress model 330. An example of a training system suitable for training the ML models 324 is described with reference to FIG. 12.

As depicted in FIG. 3, the inferencing system 300 may comprise a device 302 communicatively coupled to a set of devices 312 via a network 314. The device 302 may also be communicatively coupled to a set of devices 316 via a network 318. It may be appreciated that the inferencing system 300 may have more or less devices than shown in FIG. 3 with a different network topology as needed for a given implementation. Embodiments are not limited in this context.

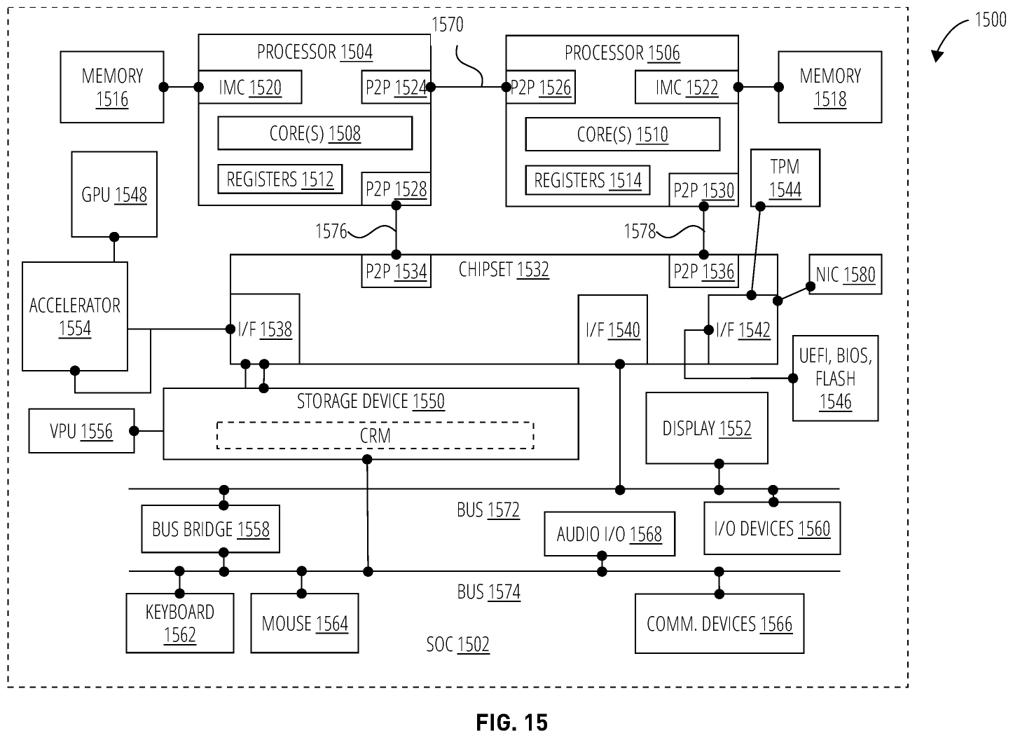

In various embodiments, the device 302 may comprise various hardware elements, such as a processing circuitry 304, a memory 306, a network interface 308, and a set of platform components 310. Similarly, the devices 312 and/or the devices 316 may include similar hardware elements as those depicted for the device 302. The device 302, devices 312, and devices 316, and associated hardware elements, are described in more detail with reference to a computing architecture 1500 as depicted in FIG. 15.

In various embodiments, the devices 302, 312 and/or 316 may communicate control, data and/or content information associated with the ion implanter 102 via one or both network 314, network 318. The network 314 and the network 318, and associated hardware elements, may be implemented in accordance with a given wireless or wired communications architecture, such as a gigabit ethernet wired network, an IEEE 802.11 (“WiFi”) wireless network, or a 3GPP 5G or 6G wireless network, among other types of networks.

The memory 306 may comprise a set of computer executable instructions that when executed by the processing circuitry 304, causes the processing circuitry 304 to manage a configuration or operation of the ion implanter 102. As depicted in FIG. 3, for example, the memory 306 may comprise a settings manager 320, a model manager 322, a set of ML models 324, and a set of setting parameters 332, among other parts. The ML models 324 include a control model 326, a variance model 328, and a stress model 330. The setting parameters 332 include one or more control parameters 334, process parameters 336, and stress parameters 338. Additionally or alternatively, the setting parameters 332 are stored in a settings database 340 accessible by the device 302. Although FIG. 3 depicts the inferencing system 300 depicted as software elements executing on hardware elements, it may be appreciated that the software elements may be implemented as hardware elements or a combination of software elements and hardware elements as needed for a given set of design constraints. Embodiments are not limited in this context.

The settings manager 320 generally manages setting parameters 332 associated with one or more components of the ion implanter 102. The settings manager 320 may perform one or more change, read, update or delete (CRUD) operations to manage the setting parameters 332 stored in the settings database 340 or the memory 306. The settings manager 320 may also read setting parameters 332 from a data source, such as components of the ion implanter 102 or input data from the GUI 342 of the electronic display 344. The settings manager 320 may also write setting parameters 332 to a data sink, such as components of the ion implanter 102 or as output data for presentation on the GUI 342 of the electronic display 344. Read operations may be useful for retrieving a current set of setting parameters 332 from components of the ion implanter 102 or the GUI 342 for updating by one or more of the ML models 324. Write operations may be useful for sending an updated set of setting parameters 332 from the ML models 324 to components of the ion implanter 102 or the GUI 342. The read and write operations may facilitate automated calibration and tuning of the components of the ion implanter 102, such as during normal PM cycles, responsive to lower production yields, or emergency disruptions. The read and write operations may also facilitate design and testing of the components of the ion implanter 102, such as for new applications.

The settings manager 320 may generate a recovery timer 348 and an estimated PM 350 for presentation by the GUI 342 on the electronic display 344. The recovery timer 348 may be a countdown timer to present a countdown of a number of time intervals (e.g., minutes, hours, days, etc.) remaining for a predicted recovery time for the ion implanter 102 to resume normal operations. The estimated PM 350 may present a time interval estimated for a next PM event for the ion implanter 102. The recovery timer 348 and the estimated PM 350 are generated from inferencing operations performed by one or more of the ML models 324, such as the variance model 328, for example.

The model manager 322 generally manages various operations for one or more ML models 324. The ML models 324 have access to various setting parameters 332, including control parameters 334, process parameters 336, and stress parameters 338. The setting parameters 332 are stored in the memory 306 or in the settings database 340.

In general, a machine learning model is a mathematical representation or algorithmic structure that learns patterns and relationships from data in order to make predictions or take decisions without being explicitly programmed. It is a key component of machine learning, which is a subfield of artificial intelligence. A machine learning model is trained on a dataset containing input data and corresponding output labels or target values. During the training process, the model iteratively adjusts its internal parameters and learns from the data, aiming to minimize the difference between its predictions and the true values. Once trained, the model can be used to make predictions or decisions on new, unseen data. It takes the learned patterns and applies them to the input data to generate output predictions or estimates.

There are various types of machine learning models, each suited to different types of tasks and problem domains. Some common categories of machine learning models include: (1) regression models used to predict continuous numerical values, such as housing prices or stock prices; (2) classification models to classify inputs into different classes or categories based on their features, such as image classification or email spam filtering; (3) clustering models to group similar instances in an unsupervised manner, without prior knowledge of the classes or categories; (4) neural networks comprising interconnected nodes (or neurons) organized into layers, with each node applying functions to the data it receives; and (5) decision trees to represent decisions and their possible consequences as a tree-like structure and are commonly used for classification and regression tasks. These are just a few examples, and there are many other types and variations of machine learning models, each designed to tackle different types of problems and data structures.

The ML models 324 include a control model 326. The control model 326 is a ML model that receives as input one or more control parameters 334 for the components and predicts one or more process parameters 336 for the components. Each of the control parameters 334 corresponds to a hardware or software setting for a component of the ion implanter 102. Examples of control parameters 334 include without limitation a charge parameter, an energy parameter, an acceleration or deceleration parameter, a dopant and flow parameter, a diluent and flow parameter, a source parameter, an analyzer parameter, a corrector parameter, a suppression parameter, a focus parameter, a scan parameter, a quadrupole lens current parameter, a post-acceleration voltage parameter, and other control parameters 334. Each of the process parameters 336 correspond to a beam property for an ion beam generated by the ion implanter. Examples of process parameters include without limitation a beam height parameter, a beam width parameter, full height half maximum (FHHM) parameter, a vertical within device angle (VWIDA) parameter, a VWIDA mean (VWIDAM) parameter, a horizontal within device angle (HWIDA) parameter, a HWIDA mean (HWIDAM) parameter, a standard deviation of VWIDA (VWIDAS) parameter, a standard deviation of HWIDA mean (HWIDAS) parameter, a vertical intensity (VI) parameter, a spotscore parameter, an energy parameter, a region of interest (ROI) current parameter, a uniformity parameter, and other process parameters 336. Embodiments are not limited to these examples.

In one embodiment, for example, the control model 326 is implemented as a feedforward model. A feedforward model is a type of neural network architecture where information flows through the network in one direction, from the input layer to the output layer, without any loops or cycles. It is called “feedforward” because the data passes through the network sequentially, layer by layer, without any feedback connections. In a feedforward model, the input data is fed into the input layer, and then it propagates forward through one or more hidden layers, where the data is transformed and processed. Finally, the transformed data is outputted by the output layer. Each layer is composed of multiple nodes (also called neurons) that perform calculations on the input data and apply linear or non-linear activation functions. The main purpose of a feedforward model is to map the input data to the desired outputs by learning the appropriate set of weights and biases associated with each node in the network. This learning process is typically accomplished through techniques such as backpropagation, where the model adjusts its parameters based on the difference between its predicted outputs and the ground truth labels. feedforward models are commonly used in various machine learning tasks, including classification, regression, and pattern recognition.

In one embodiment, the control model 326 is implemented as a control model, such as a feedforward model trained to receive an input control vector and predict an output process vector. An input control vector comprises an ordered list of values representing a set of control parameters 334 for the ion implanter 102. Each element of the input control vector corresponds to a specific value for each of the control parameters 334. The output process vector comprises an ordered list of values representing a set of process parameters 336 for the ion implanter 102 corresponding to the control parameters 334. Each element of the output process vector corresponds to a specific value for each of the process parameters 336.

The ML models 324 further include a variance model 328. As previously described, the control model 326 is trained with training data from multiple “recipes” across many different types of tools. The training data may include millions of data points spanning 700 years of collected data. The trained control model 326 is used as a pre-trained model that is used as a basis to train the variance model 328 using transfer learning. Transfer learning leverages the larger set of training data used to train the control model 326 while using far less training data points to re-train a copy of the control model 326 as the variance model 328. For example, the variance model 328 begins as a copy of the control model 326. The variance model 328 is trained to learn how predictions made by the copy of the control model 326 varies or differs from predictions made by the original control model 326. The variance model 328 is trained to learn from training data comprising strategic observations made during a PM recovery phase. Rather than retraining the entire copy of the control model 326, the variance model 328 is an ANN that only allows the innermost and outermost neural network layers to learn while the hidden layers are locked or frozen. This allows the variance model 328 to capture the major impactors expected due to various factors, such as calibration, moisture, vacuum, and other impactors experienced by the ion implanter during PM recovery. The model manager 322 track variations in predictions to identify fixed variations versus transitory variations as a way to segment residue (e.g., residual vectors) as being either new fixed calibration offsets, or position on a recovery curve (or wear curve) during operation of the ion implanter.

The ML models 324 further include a stress model 330. As the variance model 328 is a re-trained copy of the control model 326, the stress model 330 is a re-trained copy of the variance model 328. The stress model 330 takes as input a stress vector, and it outputs a model variance vector. The stress vector comprises stress parameters 338 representing all the variables that are known to have an impact over time on tool performance. Most of these are control parameters 334, some are process parameters 336 such as pure metrics like beam noise (profiler), source noise (setup cup), while others are dependent outputs. Examples of stress parameters 338 include without limitation dopant, diluent flow rates, vaporizor temperature/metal, extraction voltage/current by species and/or target mass/charge, filament current, source magnet current, cryo time since regeneration, root mean square (RMS) beam power hours, Pump/Vent, Energy, Deceleration/Acceleration modes, source type, halogen cycle tracking, charge, accelerator voltage, suppression voltage, arc voltage, and so forth. Examples of stress metrics include without limitation glitch rate, setup cup beam noise, uniformity noise, end point monitor (EPM) glitches, pumping rate, and so forth. Examples of dependent outputs include without limitation arc voltage, bias power, suppression current, arc current, filament impedance, failure due to cathode burn through, filament break, and so forth. Time-series training of the stress model 330 uses the stress vector as an input, and models the residual variation for both the input and output vector of the variance model 328 during PM recovery (e.g., from an initial high-vacuum state to a PM recovery endpoint) and normal operation (e.g., from a PM recovery endpoint to a next PM).

In operation, the inferencing system 300 can be used for predicting both PM endpoint and PM required times as previously described. Both predictions are highly valued by customers especially if they can trust the endpoint detection and minimize time and expense shooting re-qualification wafers. To this end, the device 302 of the inferencing system 300 uses one or more ML models 324, such as the stress model 330, to create a vector of accumulated values that might properly define the wear or “stress” vector over time. The stress vector may comprise, for example, a set of stress parameters 338 representing wear or stress on various components of the ion implanter 102. Examples of stress parameters 338 may include without limitation time at various levels of vacuum since venting, power and energy history on many devices, rough and high vacuum pump rates, integrated extraction currents by species, flow rates of gases and vaporizers, and other wear or stress values. The stress parameters 338 are vectorized and mapped to a vector of similar scale that can measure how current behavior of the ion implanter 102 is different from behavior measured before or after the current behavior, such as an hour before or 5 days later, for example.

Learning a high dimensional input and output regressor typically requires a large amount of training data to avoid overfitting. A good source for both data vector size and quantity is a mean process model, referred to herein as the control model 326. However, in this case, the weights and biases are modified in only in a small portion of the overall model, namely the ones that were found to change the most as a function of the stress vector. A key innovation is locking the weights and biases for the vast majority of a copy of the control model 326, which forms a basis for the variance model 328, while the variance model 328 re-learns based on observations taken during recovery. Since the degrees of freedom in training are relatively few as compared to an original training data set for the control model 326, combined with starting with a set of non-random weights but rather weights from the previous learn, the variance model 328 can converge in a relatively short time frame. The differences in the weights and biases subscribed to are analyzed, and they are harmonized with the mean stress vector predicted differences.

The resulting residuals fall into one of two categories: (1) fixed behavior or fixed variations due to mechanical alignment or new uncalibrated power supplies or other wear independent differences; or (2) transitory behavior or temporal variations due to outgassing, moisture removal, conditioning, coating, vacuum level and trace gas type, and so forth. Once a common mode of fixed variations are sufficiently identified and there is convergence to the stress model 330, a few more predictions are tested at a PM endpoint, and when they fall within an expected SPC limit, the PM recovery is considered to be complete. This model can also be used during a remaining part of an operational cycle until the next PM using the wear vector to continue to update the model weights. Except in this case, SPC variation outside limits are used to indicate when PM required as the system is no longer predictable or correctable.

A deep neural network (DNN) typically has multiple hidden layers that require a substantial amount of data and time to train. The bias and weights for the input layer to the first hidden layer can serve as a form of calibration for the inputs. Similarly, the bias and weights from the last hidden layer to the linear activation function of the output layer can be used to calibrate and/or adapt metrics. Embodiments effectively employ transfer learning by using a fully trained factory model of mean performance and “calibrating” the behavior of a fabrication ion implanter by running through a set of control inputs, represented as control parameters 334, and metric observations, represented as process parameters 336, during PM recovery or post PM calibration and locking the hidden layer biases and weights. This allows for a smaller training set and is used to train the unlocked layers, which can always start with factory model weights and biases rather than random weights and biases. This technique results in an alignment of the ion implanter 102 to a mean ion implanter 102 model and production setups over the PM cycle can be used to continue to calibrate the inner and outer layers. Normal learning would update the weights and balances of the unlocked layers which would act effectively like an adjusted linear calibration y=mx+b, where m is the weight, x is the control value and b is the bias where m and b are updated by normal backpropagation learning. The same stochastic updates to the weights and biases could be performed on any invertible function for the unlocked layers, allowing embodiments to use nonlinear functions that might have a physics based justification. These adjustments to the input and output layer can be driven by a stress vector that should allow the model to update these adjustments and validate them.

Operations for the disclosed embodiments may be further described with reference to the following figures. Some of the figures may include a logic flow. Although such figures presented herein may include a particular logic flow, it can be appreciated that the logic flow merely provides an example of how the general functionality as described herein can be implemented. Further, a given logic flow does not necessarily have to be executed in the order presented unless otherwise indicated. Moreover, not all acts illustrated in a logic flow may be required in some embodiments. In addition, the given logic flow may be implemented by a hardware element, a software element executed by a processor, or any combination thereof. The embodiments are not limited in this context.

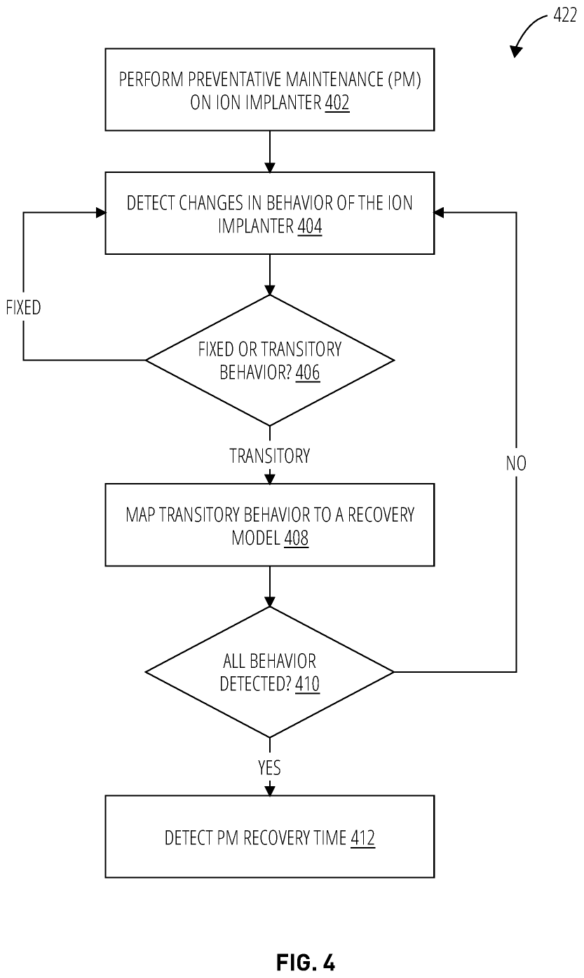

FIG. 4 illustrates an embodiment of a logic flow 422. The logic flow 422 may be representative of some or all of the operations executed by one or more embodiments described herein. For example, the logic flow 422 may include some or all of the operations performed by devices or entities within the inferencing system 300 or the device 302. More particularly, the logic flow 422 illustrates an example where the device 302 performs inferencing operations for one or more of the ML models 324, such as the variance model 328, for example.

At block 402, the logic flow 422 performs a PM on the ion implanter 102. At block 404, the logic flow 422 detects changes in behavior of the ion implanter 102. At decision block 406, the logic flow 422 determines whether the changes in behavior are fixed behavior or transitory behavior. If fixed behavior, this is added to a fixed behavior data structure, and control passes to block 404 to continue detection of changes in behavior. If transitory behavior, the logic flow 422 maps the transitory behavior to a recovery model 354. At decision block 410, the logic flow 422 determines whether all changes to behavior of the ion implanter 102 are detected. If all changes are not detected, then control is passed back to block 404. If all changes are detected, however, the logic flow 422 detects a PM recovery time 1108 predicted by the recovery model 354.

After a PM for the ion implanter 102, operators expect a certain amount of deviation from steady state behavior due to slight changes in alignment or calibration (that will remain fixed during the entire PM to next PM cycle), as well as transitory behavior due to outgas, removal of moisture and outgas, building new coatings during recovery, and so forth. Embodiments segment changes into fixed and transitory, map the transitory changes to the variance model 328, and provide quantitative endpoint detection. In addition, embodiments can track the slower transitory changes that occur from endpoint to next PM cycle in a way that can be leveraged to both estimate next PM due as well as advance the control model 326, the variance model 328 and the stress model 330 so they can keep up with wear and stress on the ion implanter 102.

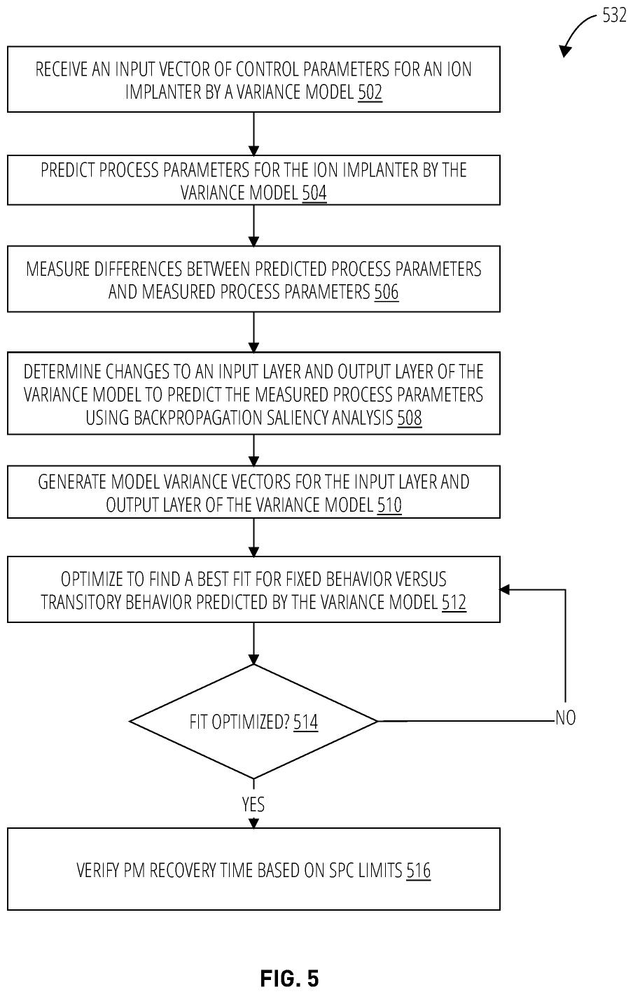

FIG. 5 illustrates an embodiment of a logic flow 532. The logic flow 532 may be representative of some or all of the operations executed by one or more embodiments described herein. For example, the logic flow 532 may include some or all of the operations performed by devices or entities within the inferencing system 300 or the device 302. More particularly, the logic flow 532 illustrates an example where the device 302 performs inferencing operations for one or more of the ML models 324, such as the variance model 328, for example.

At block 502, the logic flow 532 receives an input vector of control parameters 334 for an ion implanter 102 by a variance model 328. At block 504, the logic flow 532 predicts process parameters 336 for the ion implanter 102 by the variance model 328. At block 506, the logic flow 532 measures differences between the predicted process parameters 336 and measured process parameters 336 for the ion implanter 102. At block 508, the logic flow 532 determines changes to an input layer and an output layer of the variance model 328 to predict the measured process parameters 336 using backpropagation saliency analysis. At block 510, the logic flow 532 generates model variance vectors for the input layer and the output layer of the variance model 328. At block 512, the logic flow 532 optimizes to find a best fit for fixed behavior versus transitory behavior predicted by the variance model 328. At decision block 514, the logic flow 532 determines whether the best fit has been obtained. At block 516, the logic flow 532 verifies PM recovery time based on SPC limits.

By way of example, assume an input vector of control parameters 334 is set on the tool for one or more recipes. The feed forward network of the variance model 328 predicts an output vector of process parameters 336. The model manager 322 measures the differences between the predicted metrology and the actual metrology measured on the tool. Using backpropagation saliency analysis, a determination is made as to what needs to be changed to the input layer of the variance model 328 to get the actual values measured on the tool. This process yields two residual vectors: one for the input and one for the output. The input layer of the variance model 328 is modified by the input residual vector. This can be done via weights and biases modifications on the feed forward network of the variance model 328, or a separate nonlinear calibration layer. Similarly, the output layer could be adjusted, but only to the extent limits on the accuracy of each metric are determinable. This requires a multivariate solution over many perturbations of one or more recipes during the PM recovery phase to find the best fit between predicted and observed data given a common correction vector to the input weights/biases and output weights/biases (e.g., a relearn of forward model with all hidden layer locked) or a simple calibration layer on inputs and outputs. An optimizer finds the best fit for a common mode versus a temporal mode variance predicted by PM model. When our fit stops changing and variance model 328 model has converged with high prediction accuracy, the model manager 322 switches to a verification mode to verify precise recipe inputs and evaluate all metrology. If within SPC limits, the variance model 328 and tool are verified, calibrations locked in, and the tool is deemed PM recovery complete.

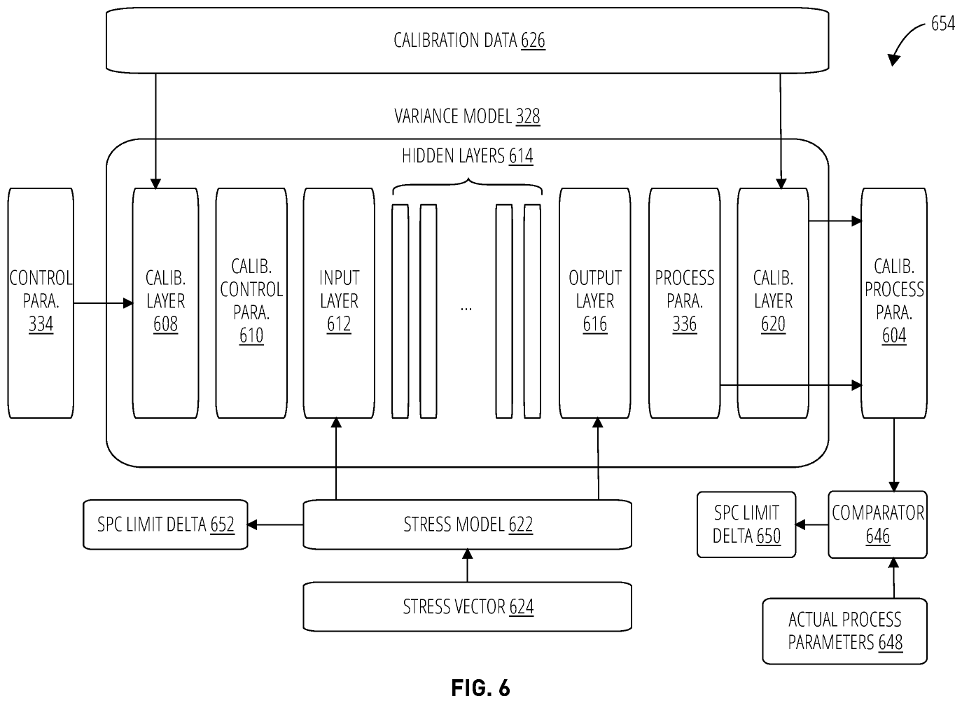

FIG. 6 illustrates an ML system 654. The ML system 654 is an example of an implementation for the ML models 324 in accordance with embodiments described herein. More particularly, the ML system 654 illustrates a variance model 328 adapted from a pre-trained control model 326 for the ion implanter 102. The ML system 654 also depicts a stress model 330 for the ion implanter 102. The ML system 654 further depicts a calibration data 626 for the variance model 328. It is worthy to note that the variance model 328 may be implemented with the stress model 330 alone, the calibration layer 608 alone, or a combination of the stress model 330 and the calibration layer 608, depending upon a particular PM task.

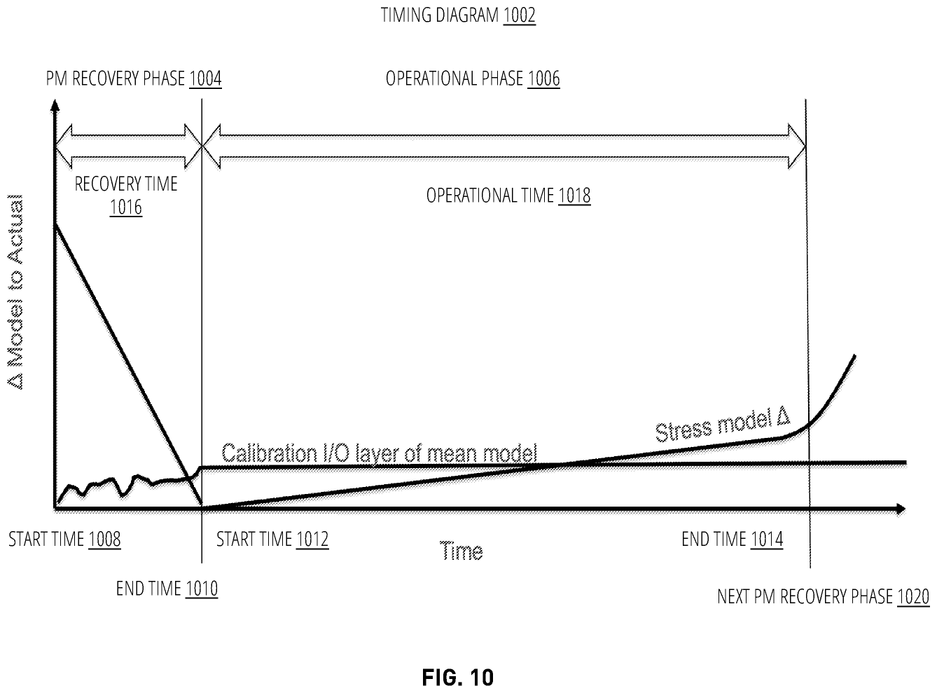

As previously described, the variance model 328 begins as a copy of a trained version of the control model 326. The variance model 328 is further trained to learn from training data comprising strategic observations made during a PM recovery phase. Rather than retraining the entire copy of the control model 326, which would require millions of data points and a significant amount of time, the variance model 328 (e.g., the copy of the trained control model 326) only allows the innermost and outermost neural network layers of the ANN to learn while the hidden layers are locked or frozen. This allows the variance model 328 to capture the major impactors expected during recovery of the ion implanter, such as calibration, moisture, vacuum, and so forth. The ML system 654 compares predictions made by the variance model 328 to predictions made by the original control model 326 to identify variations or differences, sometimes referred to as “residuals.” The ML system 654 analyzes the residuals to identify fixed behavior versus transitory behavior as a way to determine whether the residuals are new fixed calibration offsets, or alternatively, suitable for positioning on a recovery curve (or wear curve) during operation of the ion implanter. In the latter case, a recovery curve can be built by examining a residual delta between a predicted metrology and actual measured metrology of the ion implanter. The recovery curve can be used to predict a PM recovery time endpoint. An example of a recovery curve is described in FIG. 10.

In addition to transitory behaviors caused by a new configuration of the ion implanter 102 after a PM, transitory behaviors of the ion implanter may also be caused by stress or wear of the components of the ion implanter 102 over time, such as during extended periods of operation or multiple PM cycles. For example, an ion implanter 102 may experience wear such as a buildup or erosion of materials on source exit, extraction electrodes, interior surfaces, and so forth. This type of wear will impact all recipes but in different ways.

To account for stress and wear of an ion implanter 102, the ML system 654 implements the stress model 330 to model wear of components of the ion implanter 102. Instead of trying to model “wear” by itself, the ML system 654 use the same set of data used to train the control model 326 to retrain a copy of the control model 326 to form the variance model 328. In addition, the first and last layer of weights and biases are updated using tagged wear vectors, represented as stress vector 624, for example. Variations in these inner and outer layers, such as input layer 612 and output layer 616, are captured as the output vector that gets learned along with the input wear vector. The ML system 654 uses residual deltas in the variance model 328 to continue to relearn a set of observations per time increment (e.g., each hour during recovery), and evaluate the residuals to the control model 326 to predicted residuals to the stress vector 624.

For example, as depicted in FIG. 6, the variance model 328 receives as input a set of control parameters 334 for a recipe for the ion implanter 102. The variance model 328 outputs a prediction for a set of process parameters 336 corresponding to the control parameters 334. Optionally, the variance model 328 outputs a set of calibrated process parameters 604, as described below. A comparator 646 compares the process parameters 336 and/or the calibrated process parameters 604 with actual process parameters 648 measured for the ion implanter 102 at a given point in time. The comparator 646 outputs a difference value between the inputs denoted as an SPC limit delta 650. The SPC limit delta 650 may be evaluated to determine an operational state for the ion implanter 102, such as a point along a wear curve or recovery curve, as discussed in FIG. 10.

In this example, the variance model 328 is implemented as an ANN, such as a deep neural network (DNN), recurrent neural network (RNN), long short-term memory (LSTM), reservoir of recurrently connected nodes, a transformer, or other suitable ML model. The ANN comprises an input layer 612, an output layer 616, and multiple hidden layers 614. The hidden layers 614 are locked during training of the variance model 328, leaving only the input layer 612 and the output layer 616 free to have weights and biases updated by the training data.

During training, the stress model 330 receives as input a stress vector 624, and it predicts variations in weights and biases for the neurons of the input layer 612 and the output layer 616. The stress model 330 outputs model variance vectors for the input layer 612 and the output layer 616. The neurons of the input layer 612 and the output layer 616 are updated by the model variance vectors. When control parameters 334 are fed into the variance model 328, the variance model 328 predicts process parameters 336. The process parameters 336 will vary due to the variations in the input layer 612 and the output layer 616. The comparator 646 compares the process parameters 336 to the actual process parameters 648 measured for the ion implanter 102, and the result is the SPC limit delta 650. Similarly, the stress model 330 may predict an SPC limit delta 652 based on the stress vector 624. The SPC limit delta 650 and/or the SPC limit delta 652 may be used to determine an operational state for the ion implanter 102.

Optionally, the ML system 654 may implement a calibration layer 608 between the control parameters 334 and the input layer 612 and a calibration layer 620 between the output layer 616 and the output of the variance model 328. The calibration layer 608 and calibration layer 620 use calibration data 626 to perform calibration operations on the inputs and outputs of the variance model 328. For example, the calibration layer 608 may modify the control parameters 334 to account for residuals to form calibrated control parameters 610, which are then fed into the input layer 612. Similarly, the calibration layer 620 may modify the process parameters 336 to account for residuals to form calibrated process parameters 604. The calibration layer 608 and the calibration layer 620 learns only diagonal weights during PM recovery. If the stress model 330 is implemented, it can be used to improve convergence, but is not necessarily required. Implementing the optional metric calibrations may slow convergence, but could be used to identify bad metrology, such as change in Faraday opening, for example.

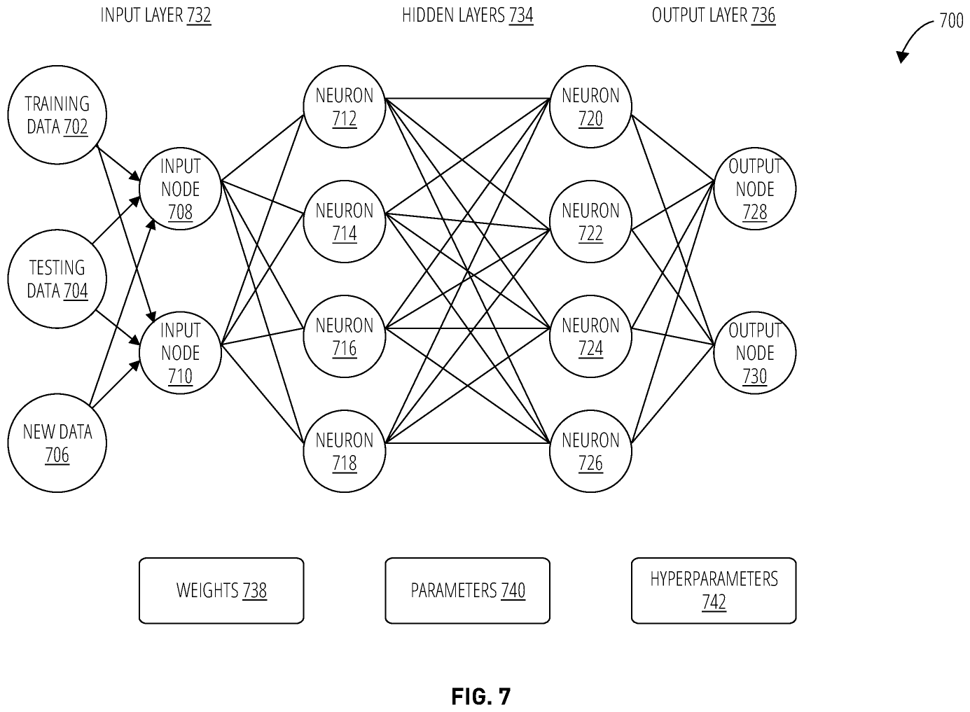

FIG. 7 illustrates an embodiment of an artificial neural network 700 suitable for use by the variance model 328. Neural networks, also known as artificial neural networks (ANNs) or simulated neural networks (SNNs), are a subset of machine learning and are at the core of deep learning algorithms. Their name and structure are inspired by the human brain, mimicking the way that biological neurons signal to one another.

Artificial neural network 700 comprises multiple node layers, containing an input layer 732, one or more hidden layers 734, and an output layer 736. Each layer comprises one or more nodes. As depicted in FIG. 7, for example, the input layer 732 has input node 708 and input node 710. The artificial neural network 700 has two hidden layers 734, with a first hidden layer having neuron 712, neuron 714, neuron 716 and neuron 718, and a second hidden layer having neuron 720, neuron 722, neuron 724 and neuron 726. The artificial neural network 700 has an output layer 736 with output node 728 and output node 730. Each node or neuron comprises a processing element (PE), or artificial neuron, that connects to another and has an associated weight and threshold. If the output of any individual node is above the specified threshold value, that node is activated, sending data to the next layer of the network. Otherwise, no data is passed along to the next layer of the network.

In general, artificial neural network 700 relies on training data 702 to learn and improve accuracy over time. However, once the artificial neural network 700 is fine-tuned for accuracy, and tested on testing data 704, the artificial neural network 700 is ready to classify and cluster new data 706 at a high velocity. Tasks in speech recognition, image recognition, or calculating continuous values can take minutes versus hours when compared to the manual identification by human experts.

The artificial neural network 700 is a linear regression model, composed of input data, weights, a bias (or threshold), and an output. Once an input layer 732 is determined, a set of weights 738 are assigned. The weights 738 help determine the importance of any given variable, with larger ones contributing more significantly to the output compared to other inputs. All inputs are then multiplied by their respective weights and then summed. Afterward, the output is passed through an activation function, which determines the output. If that output exceeds a given threshold, it “fires” (or activates) the node, passing data to the next layer in the network. This results in the output of one node becoming in the input of the next node. The process of passing data from one layer to the next layer defines the artificial neural network 700 as a feedforward network.

In one embodiment, the artificial neural network 700 leverages sigmoid neurons, which are distinguished by having values between 0 and 1. Since the artificial neural network 700 behaves similarly to a decision tree, cascading data from one node to another, having x values between 0 and 1 will reduce the impact of any given change of a single variable on the output of any given node, and subsequently, the output of the artificial neural network 700.

The artificial neural network 700 has many practical use cases, like image recognition, speech recognition, text recognition or classification. The artificial neural network 700 leverages supervised learning, or labeled datasets, to train the algorithm. As the model is trained, its accuracy is measured using a cost (or loss) function. This is also commonly referred to as the mean squared error (MSE).

Ultimately, the goal is to minimize the cost function to ensure correctness of fit for any given observation. As the model adjusts its weights and bias, it uses the cost function and reinforcement learning to reach the point of convergence, or the local minimum. The process in which the algorithm adjusts its weights is through gradient descent, allowing the model to determine the direction to take to reduce errors (or minimize the cost function). With each training example, the parameters 740 of the model adjust to gradually converge at the minimum.

In one embodiment, the artificial neural network 700 is feedforward, meaning it flows in one direction only, from input to output. In one embodiment, the artificial neural network 700 uses backpropagation. Backpropagation is when the artificial neural network 700 moves in the opposite direction from output to input. Backpropagation allows calculation and attribution of errors associated with each neuron, thereby allowing adjustment to fit the parameters 740 of the ML model 1202 appropriately.

The artificial neural network 700 is implemented as different neural networks depending on a given task. Neural networks are classified into different types, which are used for different purposes. In one embodiment, the artificial neural network 700 is implemented as a feedforward neural network, or multi-layer perceptrons (MLPs), comprised of an input layer 732, hidden layers 734, and an output layer 736. While these neural networks are also commonly referred to as MLPs, they are actually comprised of sigmoid neurons, not perceptrons, as most real-world problems are nonlinear. Trained data 1304 usually is fed into these models to train them, and they are the foundation for computer vision, natural language processing, and other neural networks. In one embodiment, the artificial neural network 700 is implemented as a convolutional neural network (CNN). A CNN is similar to feedforward networks, but usually utilized for image recognition, pattern recognition, and/or computer vision. These networks harness principles from linear algebra, particularly matrix multiplication, to identify patterns within an image. In one embodiment, the artificial neural network 700 is implemented as a recurrent neural network (RNN). A RNN is identified by feedback loops. The RNN learning algorithms are primarily leveraged when using time-series data to make predictions about future outcomes, such as stock market predictions or sales forecasting. The artificial neural network 700 is implemented as any type of neural network suitable for a given operational task of inferencing system 300, and the MLP, CNN, and RNN are merely a few examples. Embodiments are not limited in this context.

The artificial neural network 700 includes a set of associated parameters 740. There are a number of different parameters that must be decided upon when designing a neural network. Among these parameters are the number of layers, the number of neurons per layer, the number of training iterations, and so forth. Some of the more important parameters in terms of training and network capacity are a number of hidden neurons parameter, a learning rate parameter, a momentum parameter, a training type parameter, an Epoch parameter, a minimum error parameter, and so forth.

In some cases, the artificial neural network 700 is implemented as a deep learning neural network. The term deep learning neural network refers to a depth of layers in a given neural network. A neural network that has more than three layers—which would be inclusive of the inputs and the output—can be considered a deep learning algorithm. A neural network that only has two or three layers, however, may be referred to as a basic neural network. A deep learning neural network may tune and optimize one or more hyperparameters 742. A hyperparameter is a parameter whose values are set before starting the model training process. Deep learning models, including convolutional neural network (CNN) and recurrent neural network (RNN) models can have anywhere from a few hyperparameters to a few hundred hyperparameters. The values specified for these hyperparameters impacts the model learning rate and other regulations during the training process as well as final model performance. A deep learning neural network uses hyperparameter optimization algorithms to automatically optimize models. The algorithms used include Random Search, Tree-structured Parzen Estimator (TPE) and Bayesian optimization based on the Gaussian process. These algorithms are combined with a distributed training engine for quick parallel searching of the optimal hyperparameter values.

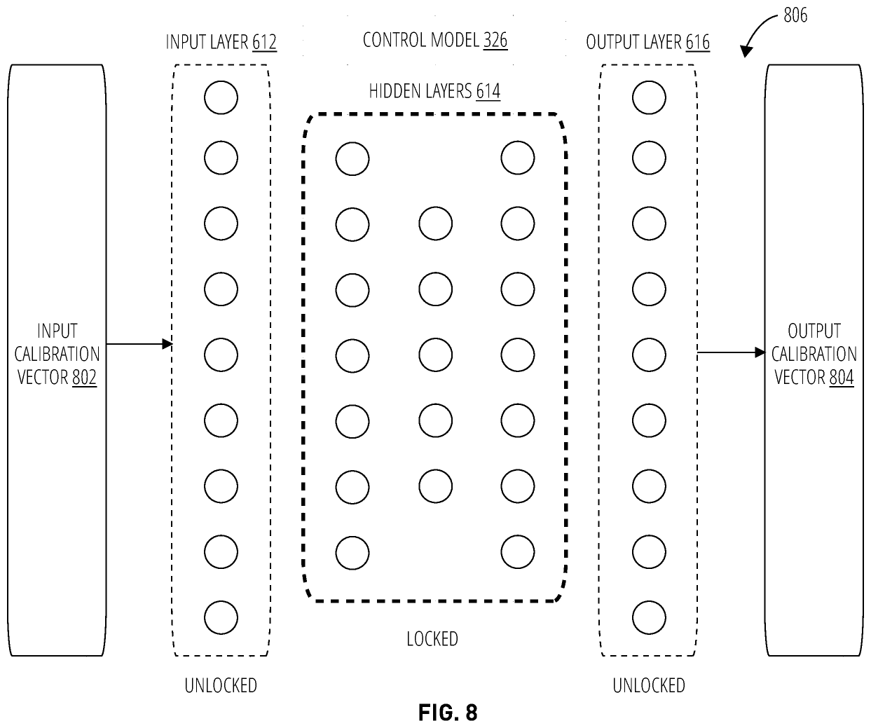

FIG. 8 illustrates an ML model 806 suitable for use by the ML system 654. Specifically, the ML model 806 illustrates an example of an implementation of the artificial neural network 700 for the variance model 328 when the calibration layer 608 and the calibration layer 620 are used.

Once the control model 326 is trained, the hidden layers 614 are locked while the input layer 612 and the output layer 616 are unlocked. The biases and weights for the input layer 612 and the output layer 616 are re-learned using the calibration data 626. The input layer 612 and the output layer 616 are the only layers trained with an option of dynamic regularization based on historical variance. Calibrating the input layer 612 and the output layer 616, while locking the hidden layers 614, requires significantly less training data for the variance model 328.

The input layer 612 receives an input calibration vector 802 with weights and biases for the input layer 612. Similarly, the output layer 616 outputs an output calibration vector 804. A residual vector is the delta between the control model 326 and the variance model 328. The residual vector has an approximate dimension given by: Vᵣₑₛ=control input count times first hidden layer size. Stochastic updates seek to weight change with a gradient toward those that show higher historical variability as predicted by, for example, a PM phase trend model. The delta to the weights and biases is an output vector that is predicted by the variance model 328 which uses the stress vector 624 for input to the stress model 330.

During a PM recovery phase, multiple predictions are maintained to identify and remove common mode changes using an optimizer during a harmonization phase. The harmonization phase seeks a best fit for segmenting from temporal variations.

The input calibration vector 802 The size of the input calibration vector 802 is less than the bias plus the input vector weights squared. In practical implementation, the size of the input calibration vector 802 is likely less due to regularization removing one or more weights, and the first hidden layer of the hidden layers 614 is a same size or smaller than the input calibration vector 802. This approach is the same for the output calibration vector 804.

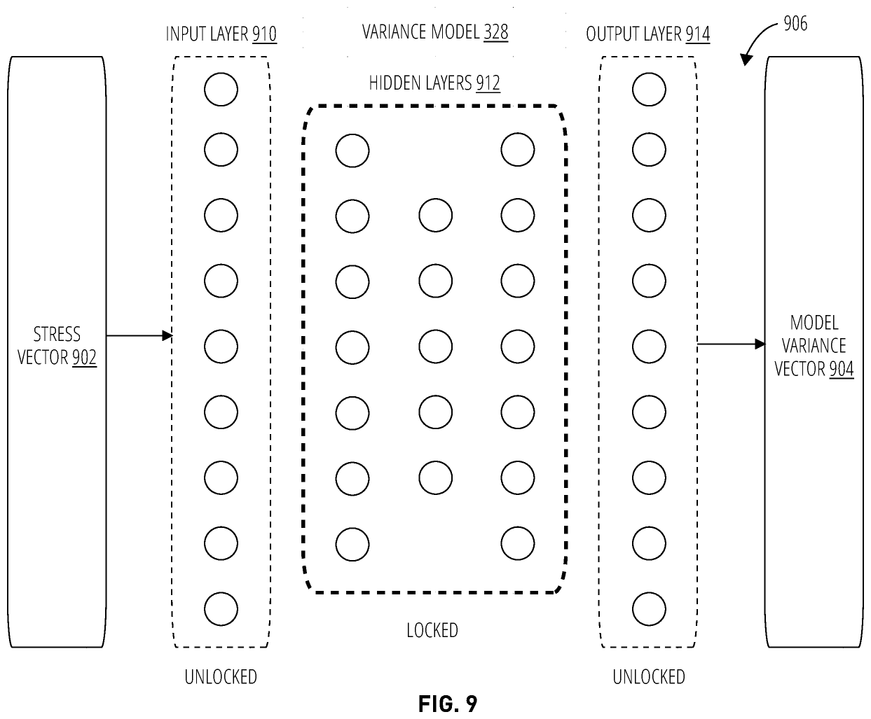

FIG. 9 illustrates an ML model 906 suitable for use by the ML system 654. Specifically, the ML model 906 illustrates an example of an implementation of the artificial neural network 700 for the stress model 330 to predict model variance vectors for updating weights and biases for the input layer 612 and the output layer 616 of the variance model 328.

As previously described, the ML models 324 include a stress model 330. As the variance model 328 is a re-trained copy of the control model 326, the stress model 330 is a re-trained copy of the variance model 328. The stress model 330 takes as input a stress vector 624, and it outputs a model variance vector 904. The stress vector 624 comprises stress parameters 338 representing all the variables that are known to have an impact over time on tool performance. Most of these are control parameters 334, some are process parameters 336 such as pure metrics like beam noise (profiler), source noise (setup cup), while others are dependent outputs. Examples of stress parameters 338 include without limitation dopant, diluent flow rates, vaporizor temperature/metal, extraction voltage/current by species and/or target mass/charge, filament current, source magnet current, cryo time since regeneration, root mean square (RMS) beam power hours, Pump/Vent, Energy, Deceleration/Acceleration modes, source type, halogen cycle tracking, charge, accelerator voltage, suppression voltage, arc voltage, and so forth. Examples of stress metrics include without limitation glitch rate, setup cup beam noise, uniformity noise, end point monitor (EPM) glitches, pumping rate, and so forth. Examples of dependent outputs include without limitation arc voltage, bias power, suppression current, arc current, filament impedance, failure due to cathode burn through, filament break, and so forth. Time-series training of the stress model 330 uses the stress vector 624 as an input, and models the residual variation for both the input and output vector of the variance model 328 during PM recovery (e.g., from an initial high-vacuum state to a PM recovery endpoint) and normal operation (e.g., from a PM recovery endpoint to a next PM).

As depicted in FIG. 9, the stress model 330 is implemented as an artificial neural network 700 similar to the trained variance model 328. As with the variance model 328, the stress model 330 comprises an input layer 910, an output layer 914, and multiple hidden layers 912. The hidden layers 912 are locked while the input layer 910 and the output layer 914 are unlocked for the stress model 330.

The stress model 330 receives as input a stress vector 624. In one embodiment, for example, the stress vector 624 may comprise a combination or extension of a total time vented, a time since last vent, source bias power hours, filament current hours, extraction current hours per gas type and per solid type, N2 bleed total volume, feed/diluent total volume, halogen cycle information, Faraday integrated power exposure per Faraday, pressure ladder per sensor, current pumping curve parameters, time since cryogenic regeneration repeated for each cryo, and so forth. The stress model 330 outputs a model variance vector 904. The model variance vector 904 is a predicted variance in mean model weights and biases for the input layer 612 and the output layer 616 of the variance model 328.

In one embodiment, for example, the model variance vector 904 is an input model variance vector that comprises weights and biases for the input layer 612 of the variance model 328. Examples for the input model variance vector 904 may include manipulate X to InNode1 weight, manipulate X to InNode 1 bias, focus voltage to Node1 weight, Q3 Main A to Node15 Weight, and so forth.

In one embodiment, for example, the model variance vector 904 is an output model variance vector that comprises weights and biases for the output layer 616 of the variance model 328. Examples for the output model variance vector 904 may include manipulate X to InNode1 weight, manipulate X to InNode 1 bias, focus voltage to Node1 weight, Q3 Main A to Node15 Weight, and so forth. Embodiments are not limited to these examples.

The ML models 324 learn a correlation between the stress vector 624 and the residual vector of the calibration layer 608 and the calibration layer 620. As previously described, the input layer 612 and the output layer 616 of the variance model 328 can be calibrated to assist in determining a PM recovery time. This results in updated weights and biases and their deltas to the control model 326 to define the calibration residual vector. The residuals are expected to change over time in a way that correlates, at least in part, to elements of the stress vector 624. The ML system 654 attempts to learn this relationship to assist in predicting and/or tracking a change in the learned residual, which is periodically updated, with the predicted change. If there is a high level of trust in predictions made by the stress model 330, then the predicted residual variation is applied to the forward model. If there is more confidence in the forward model measured residual variation, the ML system 654 can accelerate or decelerate a timeline for the stress vector 624, and adjust the expected PM required timeline.

FIG. 10 illustrates a timing diagram 1002. The timing diagram 1002 illustrates an example of harmonizing the stress model 330 and the calibration residuals. During perturbation and calibration phases of the ML models 324, the ML system 654 harmonizes the stress model 330 convergence towards a zero delta, and calibrates the inputs (e.g., minor deltas on a manipulator of the ion implanter 102, etc.) and some metrics (e.g., noise floor). When these are both harmonized, an endpoint for the PM recovery may be defined.

As depicted in FIG. 10, an x-axis of the timing diagram 1002 represents time. A y-axis of the timing diagram 1002 represents a delta between predictions made by the ML models 324 to actual metrology measured for the ion implanter 102. The ML models 324 of the inferencing system 300 are designed to predict the recovery time 1016 and the operational time 1018 for the ion implanter 102, among other operations.

The timing diagram 1002 depicts an example of a PM recovery phase 1004 for the ion implanter 102. The PM recovery phase 1004 comprises a start time 1008 and an end time 1010. The start time 1008 represents a time after a PM is performed on the ion implanter 102. The end time 1010 represents a time when the ion implanter 102 is fully operational as defined by an SPC limit. A time interval between the start time 1008 and the end time 1010 defines a recovery time 1016 for the ion implanter 102.

The timing diagram 1002 also depicts an example of an operational phase 1006 for the ion implanter 102. The operational phase 1006 comprises a start time 1012 and an end time 1014. The start time 1012 represents a time after the ion implanter 102 is deemed fully operational. The end time 1014 represents a time when the ion implanter 102 is under stress, as predicted by the stress model 330, and is due for a next PM recovery phase 1020. A time interval between the start time 1012 and the end time 1014 defines an operational time 1018 for the ion implanter 102.

The timing diagram 1002 further depicts a line representing a time to convergence between the ML models 324 and the actual metrology indicating normal steady state operations for the ion implanter 102 during the PM recovery phase 1004.

The timing diagram 1002 also depicts a line representing a calibration input/output (I/O) layer for calibrating the input vectors and output vectors of the ML models 324. Note that the calibration layer is active during the PM recovery phase 1004 of the ion implanter 102, making constant adjustments to the input and output vectors of the ML models 324, and it becomes a steady calibration offset during the operational phase 1006 of the ion implanter 102.

The timing diagram 1002 still further depicts a line representing output from the stress model 330. At start time 1012 of the operational phase 1006 the stress or wear on the newly configured ion implanter 102 is low. During the operational phase 1006, components of the ion implanter 102 become increasingly stressed in a linear fashion until it reaches an inflection point where the line starts to become exponential, thereby indicating potential failure of one or more components of the ion implanter 102. The inflection point may be an indicator of an end time 1014 of the operational phase 1006, thereby indicating a need for a next PM recovery phase 1020.

In various embodiments, the variance model 328 may be generalized or customized to a particular application. A deep neural net will perform reasonably well in learning PM variance if the stress vector 624 is designed to consider things that physics identifies as cumulative effects, such as Arsenic mA hours since source PM, for example. However, it gets more complicated with power integrations where short intervals of high power may be worse than long intervals of low power. There are similar considerations on pressure. Not only is it important to analyze a pressure level for an ion implanter 102, but also where the ion implanter 102 is on the recovery curve, how long it has been pumping, what gases are being introduced intentionally, and other factors. In such cases, the ML models 324 may be implemented with different neural net topologies, such as RNN, LSTM, Reservoir and Transformers, all of which use “loop back,” “attention” or other form of bucket brigade net integrator/differentiator topology which can learn cumulative effects or pay attention to past learning vectors. These, however, will likely take more training data and must be trained and run in sequence. A DNN model may be sufficient for must use cases.

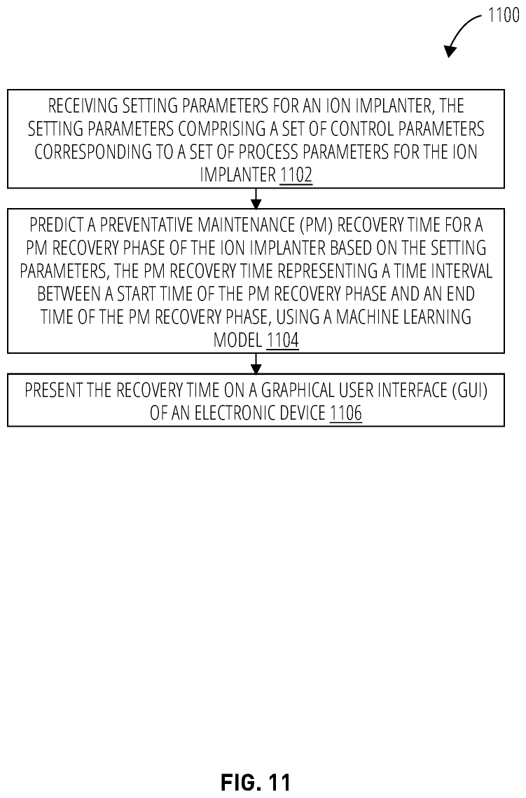

FIG. 11 illustrates a logic flow 1100. The logic flow 422 may be an example of a logic flow for one or more ML models 324, such as the variance model 328, for example. Embodiments are not limited to this example.

In block 1102, logic flow 1100 receiving setting parameters for an ion implanter, the setting parameters comprising a set of control parameters corresponding to a set of process parameters for the ion implanter. In block 1104, logic flow 1100 predicts a preventative maintenance (PM) recovery time for a PM recovery phase of the ion implanter based on the setting parameters, the PM recovery time representing a time interval between a start time of the PM recovery phase and an end time of the PM recovery phase, using a machine learning model. In block 1106, logic flow 1100 presents the recovery time on a graphical user interface (GUI) of an electronic device.

By way of example, with reference to the figures, the variance model 328 may receive setting parameters 332 for an ion implanter 102. The setting parameters 332 may include a set of control parameters 334 corresponding to a set of process parameters 336 for the ion implanter 102. A variance model 328 may predict a PM recovery time 1016 for a PM recovery phase 1004 of the ion implanter 102 based, at least in part, on the setting parameters 332. The PM recovery time 1016 represents a time interval between a start time 1008 of the PM recovery phase 1004 and an end time 1010 of the PM recovery phase 1004. The model manager 322 may present the recovery time 1016 on a GUI 342 of an electronic device 302.

In one embodiment, for example, the machine learning model is a variance model 328 implemented as an artificial neural network 700, where layers of the ANN are trained using output from a stress model 330.

In one embodiment, for example, the machine learning model is a control model 326 that is implemented as an artificial neural network 700 trained using a first set of training data and re-trained as a variance model 328 using a second set of training data, the first set of training data including setting parameters 332 and the second set of training data includes PM recovery data.

In one embodiment, for example, the machine learning model is an artificial neural network 700 including an input layer 612, an output layer 616, and multiple hidden layers 614, where the artificial neural network 700 is trained by locking the multiple hidden layers 614 and re-training the input layer 612 and the output layer 616 using PM recovery data, calibration data, or stress data.

In one embodiment, for example, the machine learning model predicts a start time for a next PM recovery phase 1020 of the ion implanter 102.

In one embodiment, for example, the machine learning model predicts the set of process parameters 336 for the ion implanter 102 from the set of control parameters 334 using the variance model 328, where the variance model 328 is adapted from a control model 326 using transfer learning. The variance model 328 determines an SPC limit delta 650 between the predicted process parameters 336 and actual process parameters 648 measured for the ion implanter 102. The model manager 322 compares the SPC limit delta 650 to a defined threshold value to obtain a comparison result, and it determines the end time 1010 of the PM recovery phase 1004 based on comparison result.

In one embodiment, for example, the control parameter corresponds to a hardware or software setting that controls a configuration or operation of a component of the ion implanter, the at least one control parameter includes a charge parameter, an energy parameter, an acceleration or deceleration parameter, a dopant and flow parameter, a diluent and flow parameter, a source parameter, an analyzer parameter, a corrector parameter, a suppression parameter, a focus parameter, a scan parameter, a quadrupole lens current parameter, or a post-acceleration voltage parameter.

In one embodiment, for example, the process parameter corresponds to a metric associated with a beam property for an ion beam generated by the ion implanter, the at least one process parameter includes a beam height parameter, a beam width parameter, full half height maximum (FHHM) parameter, a vertical within device angle (VWIDA) parameter, a VWIDA mean (VWIDAM) parameter, a horizontal within device angle (HWIDA) parameter, a HWIDA mean (HWIDAM) parameter, a standard deviation of VWIDA (VWIDAS) parameter, a standard deviation of HWIDA mean (HWIDAS) parameter, a vertical intensity (VI) parameter, a spotscore parameter, an energy parameter, a region of interest (ROI) current parameter, or a uniformity parameter.

In one embodiment, for example, the model manager 322 generates instructions, messages and/or control directives to indicate the ion implanter 102 has reached an end time 1010 of the PM recovery phase 1004 and is ready to enter an operational phase 1006 to generate an ion beam for implanting ions in a semiconductor wafer.

FIG. 12 illustrates an apparatus 1200. The apparatus 1200 depicts a training device 1216 suitable to generate a trained ML model 1202 for an inferencing device, such as the device 302 of the inferencing system 300. In one embodiment, the training device 1216 executes various ML components 1212 to generate an ML model 1202, such as a control model 326, a variance model 328 and/or a stress model 330 by performing various training, testing, and validation operations.

As depicted in FIG. 12, the training device 1216 includes a processing circuitry 1218 and a set of ML components 1212 to support various AI/ML techniques, such as a data collector 1204, a model trainer 1206, a model evaluator 1208 and a model inferencer 1210.

In general, the data collector 1204 collects data 1214 from one or more data sources to use as training data for the ML model 1202. The data collector 1204 collects different types of data 1214, such as text information, audio information, image information, video information, graphic information, and so forth. The model trainer 1206 receives as input the collected data and uses a portion of the collected data as test data for an AI/ML algorithm to train the ML model 1202. The model evaluator 1208 evaluates and improves the trained ML model 1202 using a portion of the collected data as test data to test the ML model 1202. The model evaluator 1208 also uses feedback information from the deployed ML model 1202. The model inferencer 1210 implements the trained ML model 1202 to receive as input new unseen data, generate one or more inferences on the new data, and output a result such as an alert, a recommendation or other post-solution activity.

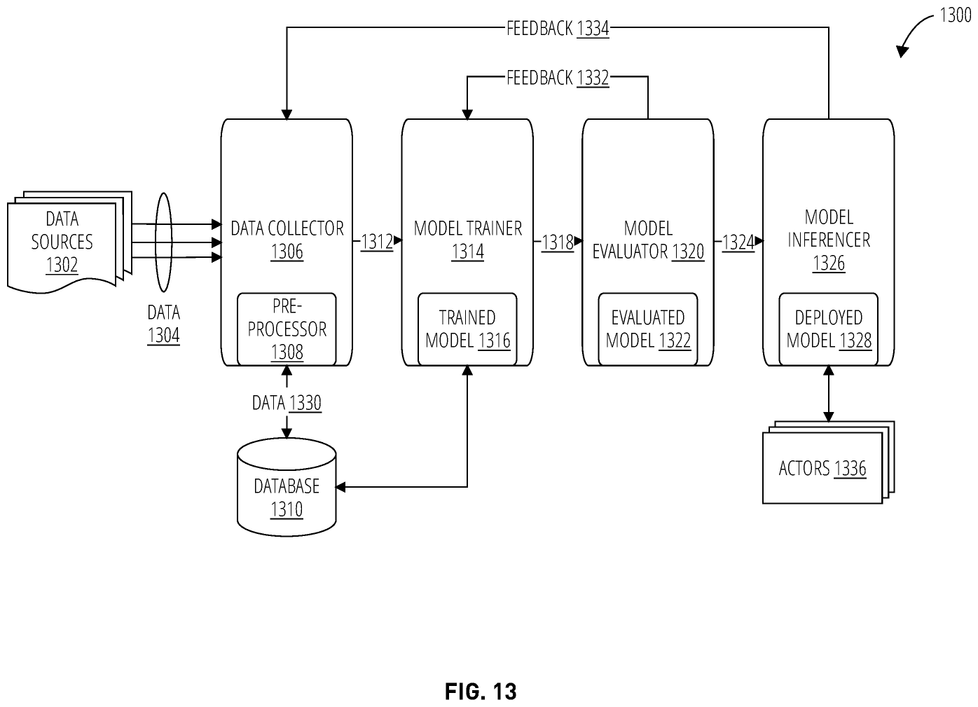

An exemplary AI/ML architecture for the ML components 1212 is described in more detail with reference to FIG. 13.

FIG. 13 illustrates a training system 1300. The training system 1300 is an example of a system suitable for implementing various artificial intelligence (AI) techniques and/or machine learning (ML) techniques to perform various tasks. AI is a science and technology based on principles of cognitive science, computer science and other related disciplines, which deals with the creation of intelligent machines that work and react like humans. AI is used to develop systems that can perform tasks that require human intelligence such as recognizing speech, vision and making decisions. AI can be seen as the ability for a machine or computer to think and learn, rather than just following instructions. ML is a subset of AI that uses algorithms to enable machines to learn from existing data and generate insights or predictions from that data. ML algorithms are used to optimize machine performance in various tasks such as classifying, clustering and forecasting. ML algorithms are used to create ML models that can accurately predict outcomes.

In general, the training system 1300 may include various machine or computer components (e.g., circuit, processor circuit, memory, network interfaces, compute platforms, input/output (I/O) devices, etc.) for an AI/ML system that are designed to work together to create a pipeline that can take in raw data, process it, train a ML model, evaluate its performance, deploy it in a production environment, and continuously monitor and maintain it.

A ML model is a mathematical construct used to predict outcomes based on a set of input data. ML models are trained using large volumes of data, and they can recognize patterns and trends in that data to make accurate predictions. The ML models are derived from different ML algorithms. The ML algorithms may comprise supervised algorithms, unsupervised algorithms, or semi-supervised algorithms.

A supervised algorithm is a type of machine learning algorithm that uses labeled data to train a model. In supervised learning, the algorithm is given a set of input data and corresponding output data, which are used to train the model to make predictions or classifications. The input data is also known as the features, and the output data is known as the target or label. The goal of a supervised algorithm is to learn the relationship between the input features and the target labels, so that it can make accurate predictions or classifications for new, unseen data. Examples of supervised learning algorithms include: (1) linear regression which is a regression algorithm used to predict continuous numeric values, such as stock prices or temperature; (2) logistic regression which is a classification algorithm used to predict binary outcomes, such as whether a customer will churn or not; (3) decision tree which is a classification algorithm used to predict categorical outcomes by creating a decision tree based on the input features; or (4) random forest which is an ensemble algorithm that combines multiple decision trees to make more accurate predictions.

An unsupervised algorithm is a type of machine learning algorithm that is used to find patterns and relationships in a dataset without the need for labeled data. Unlike supervised learning, where the algorithm is provided with labeled training data and learns to make predictions based on that data, unsupervised learning works with unlabeled data and seeks to identify underlying structures or patterns. Unsupervised learning algorithms use a variety of techniques to discover patterns in the data, such as clustering, anomaly detection, and dimensionality reduction. Clustering algorithms group similar data points together, while anomaly detection algorithms identify unusual or unexpected data points. Dimensionality reduction algorithms are used to reduce the number of features in a dataset, making it easier to analyze and visualize. Unsupervised learning has many applications, such as in data mining, pattern recognition, and recommendation systems. It is particularly useful for tasks where labeled data is scarce or difficult to obtain, and where the goal is to gain insights and understanding from the data itself rather than to make predictions based on it.

Semi-supervised learning is a type of machine learning algorithm that combines both labeled and unlabeled data to improve the accuracy of predictions or classifications. In this approach, the algorithm is trained on a small amount of labeled data and a much larger amount of unlabeled data. The main idea behind semi-supervised learning is that labeled data is often scarce and expensive to obtain, whereas unlabeled data is abundant and easy to collect. By leveraging both types of data, semi-supervised learning can achieve higher accuracy and better generalization than either supervised or unsupervised learning alone. In semi-supervised learning, the algorithm first uses the labeled data to learn the underlying structure of the problem. It then uses this knowledge to identify patterns and relationships in the unlabeled data, and to make predictions or classifications based on these patterns. Semi-supervised learning has many applications, such as in speech recognition, natural language processing, and computer vision. It is particularly useful for tasks where labeled data is expensive or time-consuming to obtain, and where the goal is to improve the accuracy of predictions or classifications by leveraging large amounts of unlabeled data.

The training system 1300 may implement various types of ML algorithms including supervised algorithms, unsupervised algorithms, semi-supervised algorithms, or a combination thereof. A few examples of ML algorithms include support vector machine (SVM), random forests, naive Bayes, K-means clustering, neural networks, and so forth. A SVM is an algorithm that can be used for both classification and regression problems. It works by finding an optimal hyperplane that maximizes the margin between the two classes. Random forests is a type of decision tree algorithm that is used to make predictions based on a set of randomly selected features. Naive Bayes is a probabilistic classifier that makes predictions based on the probability of certain events occurring. K-Means Clustering is an unsupervised learning algorithm that groups data points into clusters. Neural networks is a type of machine learning algorithm that is designed to mimic the behavior of neurons in the human brain. Other examples of ML algorithms include an artificial neural network (ANN), convolutional neural network (CNN), deep learning, decision tree learning, support-vector machine, regression analysis, Bayesian networks, genetic algorithms, federated learning, distributed artificial intelligence, and various other ML algorithms.

As depicted in FIG. 13, the training system 1300 includes a set of data sources 1302 to source data 1304 for the training system 1300. Data sources 1302 may comprise any device capable generating, processing, storing or managing data 1304 suitable for a ML system. Examples of data sources 1302 include without limitation databases, web scraping, sensors and Internet of Things (IoT) devices, image and video cameras, audio devices, text generators, publicly available databases, private databases, and many other data sources 1302. The data sources 1302 may be remote from the training system 1300 and accessed via a network, local to the training system 1300 an accessed via a network interface, or may be a combination of local and remote data sources 1302.

The data sources 1302 may source difference types of data 1304. For instance, the data 1304 may comprise structured data from relational databases, such as customer profiles, transaction histories, or product inventories. The data 1304 may comprise unstructured data from websites such as customer reviews, news articles, social media posts, or product specifications. The data 1304 may comprise data from temperature sensors, motion detectors, and smart home appliances. The data 1304 may comprise image data from medical images, security footage, or satellite images. The data 1304 may comprise audio data from speech recognition, music recognition, or call centers. The data 1304 may comprise text data from emails, chat logs, customer feedback, news articles or social media posts. The data 1304 may comprise publicly available datasets such as those from government agencies, academic institutions, or research organizations. These are just a few examples of the many sources of data that can be used for ML systems. It is important to note that the quality and quantity of the data is critical for the success of a machine learning project.

The data 1304 can be in different formats such as structured, unstructured or semi-structured data. Structured data refers to data that is organized in a specific format or schema, such as tables or spreadsheets. Structured data has a well-defined set of rules that dictate how the data should be organized and represented, including the data types and relationships between data elements. Unstructured data refers to any data that does not have a predefined or organized format or schema. Unlike structured data, which is organized in a specific way, unstructured data can take various forms, such as text, images, audio, or video. Unstructured data can come from a variety of sources, including social media, emails, sensor data, and website content. Semi-structured data is a type of data that does not fit neatly into the traditional categories of structured and unstructured data. It has some structure but does not conform to the rigid structure of a traditional relational database. Semi-structured data is characterized by the presence of tags or metadata that provide some structure and context for the data.

The data sources 1302 may be communicatively coupled to a data collector 1306. The data collector 1306 gathers relevant data 1304 from the data sources 1302. Once collected, the data collector 1306 may use a pre-processor 1308 to make the data 1304 suitable for analysis. This involves data cleaning, transformation, and feature engineering. Data preprocessing is a critical step in ML as it directly impacts the accuracy and effectiveness of the model. The pre-processor 1308 may receive the data 1304 as input, process the data 1304, and output pre-processed data 1330 for storage in a database 1310. The database 1310 may comprise a hard drive, solid state storage, and/or random access memory.

The data collector 1306 may be communicatively coupled to a model trainer 1314. The model trainer 1314 performs AI/ML model training, validation, and testing which may generate model performance metrics as part of the model testing procedure. The model trainer 1314 may receive the pre-processed data 1330 as input 1312 or via the database 1310. The model trainer 1314 may implement a suitable ML algorithm to train an ML model on the pre-processed data 1330. The training process involves feeding the pre-processed data 1330 into a ML model to form a trained model 1316. The training process adjusts its parameters until it achieves an initial level of satisfactory performance.

The model trainer 1314 may be communicatively coupled to a model evaluator 1320. After a ML model is trained, the trained model 1316 needs to be evaluated to assess its performance. This is done using various metrics such as accuracy, precision, recall, and F1 score. The model trainer 1314 may output the trained model 1316, which is received as input 1312. The model evaluator 1320 receives the trained model 1316, and it initiates an evaluation process to measure performance of the trained model 1316. The evaluation process may include providing feedback 1332 to the model trainer 1314, so that it may re-train the trained model 1316 to improve performance in an iterative manner.

The model evaluator 1320 may be communicatively coupled to a model inferencer 1326. The model inferencer 1326 provides AI/ML model inference output (e.g., predictions or decisions). Once the ML model is trained and evaluated, it can be deployed in a production environment where it can be used to make predictions on new data. The model inferencer 1326 receives the evaluated model 1322 as input 1324. The model inferencer 1326 may use the evaluated model 1322 as a deployed model 1328, which is a final production ML model. The inference output of the deployed model 1328 is use case specific. The model inferencer 1326 may also perform model monitoring and maintenance, which involves continuously monitoring performance of the deployed model 1328 in the production environment and making any necessary updates or modifications to maintain its accuracy and effectiveness. The model inferencer 1326 may provide feedback 1332 to the data collector 1306 to train or re-train the ML model. The feedback 1332 may include model performance feedback information, which may be used for monitoring and improving performance of the deployed model 1328.

The model inferencer 1326 may be implemented by various actors 1336 in the training system 1300. The actors 1336 may use the deployed model 1328 on new data to make inferences or predictions for a given task. The actors 1336 may actually implement the model inferencer 1326, or receive outputs from the model inferencer 1326 in a distributed computing manner. The actors 1336 may trigger actions directed to other entities or to itself. The actors 1336 may provide feedback 1334 to the data collector 1306 via the model inferencer 1326. The feedback 1334 may comprise data needed to derive training data, inference data or to monitor the performance of the AI/ML model and its impact to the network through updating of key performance indicators (KPIs) and performance counters.

The training system 1300 may be applicable to various use cases and solutions for AI/ML tasks, such as the inferencing system 300 and/or training system 1300. Other use cases and solutions for AI/ML are possible as well, and embodiments are not limited in this context.

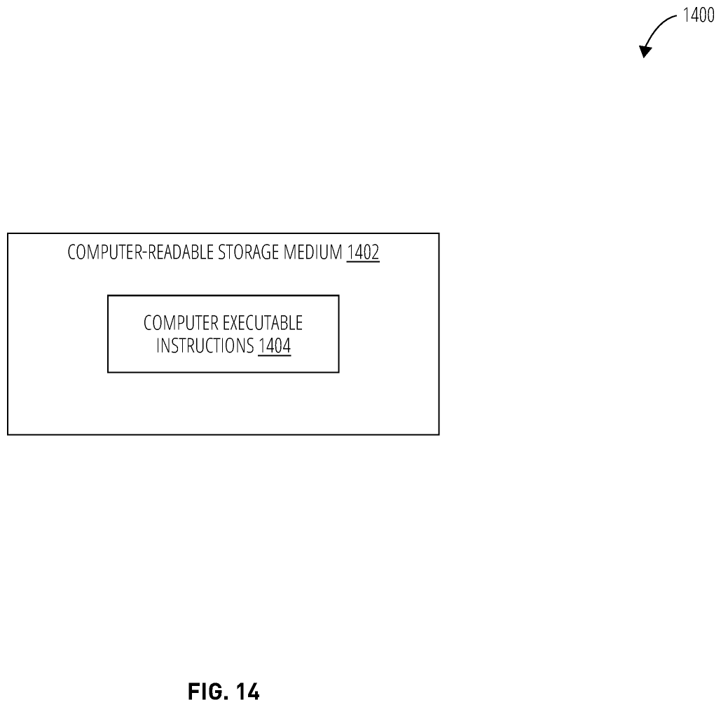

FIG. 14 illustrates an apparatus 1400. Apparatus 1400 may comprise any non-transitory computer-readable storage medium 1402 or machine-readable storage medium, such as an optical, magnetic or semiconductor storage medium. In various embodiments, apparatus 1400 may comprise an article of manufacture or a product. In some embodiments, the computer-readable storage medium 1402 may store computer executable instructions with which circuitry can execute. For example, computer executable instructions 1404 can include instructions to implement operations described with respect to any logic flows described herein. Examples of computer-readable storage medium 1402 or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions 1404 may include any suitable type of code, such as source code, compiled code, interpreted code, executable code, static code, dynamic code, object-oriented code, visual code, and the like.

FIG. 15 illustrates an embodiment of a computing architecture 1500. Computing architecture 1500 is a computer system with multiple processor cores such as a distributed computing system, supercomputer, high-performance computing system, computing cluster, mainframe computer, mini-computer, client-server system, personal computer (PC), workstation, server, portable computer, laptop computer, tablet computer, handheld device such as a personal digital assistant (PDA), or other device for processing, displaying, or transmitting information. Similar embodiments may comprise, e.g., entertainment devices such as a portable music player or a portable video player, a smart phone or other cellular phone, a telephone, a digital video camera, a digital still camera, an external storage device, or the like. Further embodiments implement larger scale server configurations. In other embodiments, the computing architecture 1500 may have a single processor with one core or more than one processor. Note that the term “processor” refers to a processor with a single core or a processor package with multiple processor cores. In at least one embodiment, the computing architecture 1500 is representative of the components of the inferencing system 300. More generally, the computing architecture 1500 is configured to implement all logic, systems, logic flows, methods, apparatuses, and functionality described herein with reference to previous figures.

As used in this application, the terms “system” and “component” and “module” are intended to refer to a computer-related entity, either hardware, a combination of hardware and software, software, or software in execution, examples of which are provided by the exemplary computing architecture 1500. For example, a component can be, but is not limited to being, a process running on a processor, a processor, a hard disk drive, multiple storage drives (of optical and/or magnetic storage medium), an object, an executable, a thread of execution, a program, and/or a computer. By way of illustration, both an application running on a server and the server can be a component. One or more components can reside within a process and/or thread of execution, and a component can be localized on one computer and/or distributed between two or more computers. Further, components may be communicatively coupled to each other by various types of communications media to coordinate operations. The coordination may involve the uni-directional or bi-directional exchange of information. For instance, the components may communicate information in the form of signals communicated over the communications media. The information can be implemented as signals allocated to various signal lines. In such allocations, each message is a signal. Further embodiments, however, may alternatively employ data messages. Such data messages may be sent across various connections. Exemplary connections include parallel interfaces, serial interfaces, and bus interfaces.

As shown in FIG. 15, computing architecture 1500 comprises a system-on-chip (SoC) 1502 for mounting platform components. System-on-chip (SoC) 1502 is a point-to-point (P2P) interconnect platform that includes a first processor 1504 and a second processor 1506 coupled via a point-to-point interconnect 1570 such as an Ultra Path Interconnect (UPI). In other embodiments, the computing architecture 1500 may be of another bus architecture, such as a multi-drop bus. Furthermore, each of processor 1504 and processor 1506 may be processor packages with multiple processor cores including core(s) 1508 and core(s) 1510, respectively. While the computing architecture 1500 is an example of a two-socket (2S) platform, other embodiments may include more than two sockets or one socket. For example, some embodiments may include a four-socket (4S) platform or an eight-socket (8S) platform. Each socket is a mount for a processor and may have a socket identifier. Note that the term platform may refers to a motherboard with certain components mounted such as the processor 1504 and chipset 1532. Some platforms may include additional components and some platforms may only include sockets to mount the processors and/or the chipset. Furthermore, some platforms may not have sockets (e.g. SoC, or the like). Although depicted as a SoC 1502, one or more of the components of the SoC 1502 may also be included in a single die package, a multi-chip module (MCM), a multi-die package, a chiplet, a bridge, and/or an interposer. Therefore, embodiments are not limited to a SoC.

The processor 1504 and processor 1506 can be any of various commercially available processors, including without limitation an Intel® Celeron®, Core®, Core (2) Duo®, Itanium®, Pentium®, Xeon®, and XScale® processors; AMD® Athlon®, Duron® and Opteron® processors; ARM® application, embedded and secure processors; IBM® and Motorola® DragonBall® and PowerPC® processors; IBM and Sony® Cell processors; and similar processors. Dual microprocessors, multi-core processors, and other multi-processor architectures may also be employed as the processor 1504 and/or processor 1506. Additionally, the processor 1504 need not be identical to processor 1506.

Processor 1504 includes an integrated memory controller (IMC) 1520 and point-to-point (P2P) interface 1524 and P2P interface 1528. Similarly, the processor 1506 includes an IMC 1522 as well as P2P interface 1526 and P2P interface 1530. IMC 1520 and IMC 1522 couple the processor 1504 and processor 1506, respectively, to respective memories (e.g., memory 1516 and memory 1518). Memory 1516 and memory 1518 may be portions of the main memory (e.g., a dynamic random-access memory (DRAM)) for the platform such as double data rate type 4 (DDR4) or type 5 (DDR5) synchronous DRAM (SDRAM). In the present embodiment, the memory 1516 and the memory 1518 locally attach to the respective processors (i.e., processor 1504 and processor 1506). In other embodiments, the main memory may couple with the processors via a bus and shared memory hub. Processor 1504 includes registers 1512 and processor 1506 includes registers 1514.

Computing architecture 1500 includes chipset 1532 coupled to processor 1504 and processor 1506. Furthermore, chipset 1532 can be coupled to storage device 1550, for example, via an interface (I/F) 1538. The I/F 1538 may be, for example, a Peripheral Component Interconnect-enhanced (PCIe) interface, a Compute Express Link® (CXL) interface, or a Universal Chiplet Interconnect Express (UCIe) interface. Storage device 1550 can store instructions executable by circuitry of computing architecture 1500 (e.g., processor 1504, processor 1506, GPU 1548, accelerator 1554, vision processing unit 1556, or the like). For example, storage device 1550 can store instructions for device 302, devices 312, devices 316, or the like.

Processor 1504 couples to the chipset 1532 via P2P interface 1528 and P2P 1534 while processor 1506 couples to the chipset 1532 via P2P interface 1530 and P2P 1536. Direct media interface (DMI) 1576 and DMI 1578 may couple the P2P interface 1528 and the P2P 1534 and the P2P interface 1530 and P2P 1536, respectively. DMI 1576 and DMI 1578 may be a high-speed interconnect that facilitates, e.g., eight Giga Transfers per second (GT/s) such as DMI 3.0. In other embodiments, the processor 1504 and processor 1506 may interconnect via a bus.

The chipset 1532 may comprise a controller hub such as a platform controller hub (PCH). The chipset 1532 may include a system clock to perform clocking functions and include interfaces for an I/O bus such as a universal serial bus (USB), peripheral component interconnects (PCIs), CXL interconnects, UCIe interconnects, interface serial peripheral interconnects (SPIs), integrated interconnects (I2Cs), and the like, to facilitate connection of peripheral devices on the platform. In other embodiments, the chipset 1532 may comprise more than one controller hub such as a chipset with a memory controller hub, a graphics controller hub, and an input/output (I/O) controller hub.

In the depicted example, chipset 1532 couples with a trusted platform module (TPM) 1544 and UEFI, BIOS, FLASH circuitry 1546 via I/F 1542. The TPM 1544 is a dedicated microcontroller designed to secure hardware by integrating cryptographic keys into devices. The UEFI, BIOS, FLASH circuitry 1546 may provide pre-boot code.

Furthermore, chipset 1532 includes the I/F 1538 to couple chipset 1532 with a high-performance graphics engine, such as, graphics processing circuitry or a graphics processing unit (GPU) 1548. In other embodiments, the computing architecture 1500 may include a flexible display interface (FDI) (not shown) between the processor 1504 and/or the processor 1506 and the chipset 1532. The FDI interconnects a graphics processor core in one or more of processor 1504 and/or processor 1506 with the chipset 1532.

The computing architecture 1500 is operable to communicate with wired and wireless devices or entities via the network interface (NIC) 180 using the IEEE 802 family of standards, such as wireless devices operatively disposed in wireless communication (e.g., IEEE 802.11 over-the-air modulation techniques). This includes at least Wi-Fi (or Wireless Fidelity), WiMax, and Bluetooth™ wireless technologies, 3G, 4G, LTE wireless technologies, among others. Thus, the communication can be a predefined structure as with a conventional network or simply an ad hoc communication between at least two devices. Wi-Fi networks use radio technologies called IEEE 802.11x (a, b, g, n, ac, ax, etc.) to provide secure, reliable, fast wireless connectivity. A Wi-Fi network can be used to connect computers to each other, to the Internet, and to wired networks (which use IEEE 802.3-related media and functions).

Additionally, accelerator 1554 and/or vision processing unit 1556 can be coupled to chipset 1532 via I/F 1538. The accelerator 1554 is representative of any type of accelerator device (e.g., a data streaming accelerator, cryptographic accelerator, cryptographic co-processor, an offload engine, etc.). One example of an accelerator 1554 is the Intel® Data Streaming Accelerator (DSA). The accelerator 1554 may be a device including circuitry to accelerate copy operations, data encryption, hash value computation, data comparison operations (including comparison of data in memory 1516 and/or memory 1518), and/or data compression. For example, the accelerator 1554 may be a USB device, PCI device, PCIe device, CXL device, UCIe device, and/or an SPI device. The accelerator 1554 can also include circuitry arranged to execute machine learning (ML) related operations (e.g., training, inference, etc.) for ML models. Generally, the accelerator 1554 may be specially designed to perform computationally intensive operations, such as hash value computations, comparison operations, cryptographic operations, and/or compression operations, in a manner that is more efficient than when performed by the processor 1504 or processor 1506. Because the load of the computing architecture 1500 may include hash value computations, comparison operations, cryptographic operations, and/or compression operations, the accelerator 1554 can greatly increase performance of the computing architecture 1500 for these operations.

The accelerator 1554 may include one or more dedicated work queues and one or more shared work queues (each not pictured). Generally, a shared work queue is configured to store descriptors submitted by multiple software entities. The software may be any type of executable code, such as a process, a thread, an application, a virtual machine, a container, a microservice, etc., that share the accelerator 1554. For example, the accelerator 1554 may be shared according to the Single Root I/O virtualization (SR-IOV) architecture and/or the Scalable I/O virtualization (S-IOV) architecture. Embodiments are not limited in these contexts. In some embodiments, software uses an instruction to atomically submit the descriptor to the accelerator 1554 via a non-posted write (e.g., a deferred memory write (DMWr)). One example of an instruction that atomically submits a work descriptor to the shared work queue of the accelerator 1554 is the ENQCMD command or instruction (which may be referred to as “ENQCMD” herein) supported by the Intel® Instruction Set Architecture (ISA). However, any instruction having a descriptor that includes indications of the operation to be performed, a source virtual address for the descriptor, a destination virtual address for a device-specific register of the shared work queue, virtual addresses of parameters, a virtual address of a completion record, and an identifier of an address space of the submitting process is representative of an instruction that atomically submits a work descriptor to the shared work queue of the accelerator 1554. The dedicated work queue may accept job submissions via commands such as the movdir64b instruction.

Various I/O devices 1560 and display 1552 couple to the bus 1572, along with a bus bridge 1558 which couples the bus 1572 to a second bus 1574 and an I/F 1540 that connects the bus 1572 with the chipset 1532. In one embodiment, the second bus 1574 may be a low pin count (LPC) bus. Various devices may couple to the second bus 1574 including, for example, a keyboard 1562, a mouse 1564 and communication devices 1566.

Furthermore, an audio I/O 1568 may couple to second bus 1574. Many of the I/O devices 1560 and communication devices 1566 may reside on the system-on-chip (SoC) 1502 while the keyboard 1562 and the mouse 1564 may be add-on peripherals. In other embodiments, some or all the I/O devices 1560 and communication devices 1566 are add-on peripherals and do not reside on the system-on-chip (SoC) 1502.

The components and features of the devices described above may be implemented using any combination of discrete circuitry, application specific integrated circuits (ASICs), logic gates and/or single chip architectures. Further, the features of the devices may be implemented using microcontrollers, programmable logic arrays and/or microprocessors or any combination of the foregoing where suitably appropriate. It is noted that hardware, firmware and/or software elements may be collectively or individually referred to herein as “logic” or “circuit.”

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in embodiments.

At least one computer-readable storage medium may include instructions that, when executed, cause a system to perform any of the computer-implemented methods described herein.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately may be employed in combination with each other unless it is noted that the features are incompatible with each other.

With general reference to notations and nomenclature used herein, the detailed descriptions herein may be presented in terms of program procedures executed on a computer or network of computers. These procedural descriptions and representations are used by those skilled in the art to most effectively convey the substance of their work to others skilled in the art.

A procedure is here, and generally, conceived to be a self-consistent sequence of operations leading to a desired result. These operations are those requiring physical manipulations of physical quantities. Usually, though not necessarily, these quantities take the form of electrical, magnetic or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Further, the manipulations performed are often referred to in terms, such as adding or comparing, which are commonly associated with mental operations performed by a human operator. No such capability of a human operator is necessary, or desirable in most cases, in any of the operations described herein, which form part of one or more embodiments. Rather, the operations are machine operations. Useful machines for performing operations of various embodiments include general purpose digital computers or similar devices.

Some embodiments may be described using the expression “coupled” and “connected” along with their derivatives. These terms are not necessarily intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

Various embodiments also relate to apparatus or systems for performing these operations. This apparatus may be specially constructed for the required purpose or it may comprise a general purpose computer as selectively activated or reconfigured by a computer program stored in the computer. The procedures presented herein are not inherently related to a particular computer or other apparatus. Various general purpose machines may be used with programs written in accordance with the teachings herein, or it may prove convenient to construct more specialized apparatus to perform the required method steps. The required structure for a variety of these machines will appear from the description given.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims.

The various elements of the devices as previously described with reference to FIGS. 1—may include various hardware elements, software elements, or a combination of both. Examples of hardware elements may include devices, logic devices, components, processors, microprocessors, circuits, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements may include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that make the logic or processor. Some embodiments may be implemented, for example, using a machine-readable medium or article which may store an instruction or a set of instructions that, if executed by a machine, may cause the machine to perform a method and/or operations in accordance with the embodiments. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions may include any suitable type of code, such as source code, compiled code, interpreted code, executable code, static code, dynamic code, encrypted code, and the like, implemented using any suitable high-level, low-level, object-oriented, visual, compiled and/or interpreted programming language.

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in embodiments.

At least one computer-readable storage medium may include instructions that, when executed, cause a system to perform any of the computer-implemented methods described herein.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately may be employed in combination with each other unless it is noted that the features are incompatible with each other.

### Terminology

Tool Implant Metrics—Objects to measure to confirm wafer will be implanted as expected, e.g., energy, species, charge, ROI current, beam height, beam width, angles, angle spread, etc.

Control Inputs/Tuning Knobs—Set of parameters used to create desired Tool Implant Metrics, e.g., Accelerator Manipulator position, Analyzer Current, Focus Voltage, Extraction Voltage, Q3, Corrector Current, etc.

Dependent Outputs—parameters which vary with control inputs but are not part of the set of process metrics. For example, using a current controller setting as an input, but use its voltage feedback as a dependent output for inferring impedance.

Stress Vector—set of parameters that measure wear and tear on tool, e.g., extraction current & voltage hours by species, gas flow rates, pump/vent cycles, robot moves, etc.

Guide Star Alignment (GSA)—the use of specific setups to do long optical baseline alignment such as source magnet to filter magnet to manipulator to analyzer to corrector to MPXL beam X offset.

Perturbation Sequences for Alignment and Calibration (PSAC)-single GSA can be inconclusive due to combined interactions of Manipulator, Analyzer Current (multiple unknowns). Orthogonal perturbations can provide sufficient ‘multiple equations’ for solving ‘multiple unknowns’ for n-dimensional calibration

Process Param Sieve—Large set of process params (Metrics) derived from training set and/or forward process model stored as large vector set (˜100,000). As customers pin down aspects of desired process params, the set intersection is calculated, with user input restricted to set intersection. This makes sure that the desired process parameters can be achieved by the tool. Can be used offline and displayed as set of micro histograms that adjust to process param windows

Back Propagation (Stochastic)—working backwards from outputs to inputs, assessing what minor nudge to previous layer results in a move towards the desired output (i.e. do a better job predicting the output). These are done in batches, with the nudges stochastically combined.

Locked Layer Learning—Allows Back Propagation to pass through Neural Net (NN) layers for the purpose of updating only those layers that are not locked.

Gradient Based Saliency Map—back propagation of an output difference or perturbation to identify the most important inputs that affected that difference.

Regression Neural Network—unlike a classifier network, which uses a Boolean activation function (each neuron evaluates to 0 or 1), a regression NN uses a linear activation function (a bias plus a sum of all values connecting from previous layer). The result is a continuous output value.

Transfer Learning—Model trained on one thing can be repurposed to do a related task.

Invertible Neural Network (INN)—If input layer variation always results in unique outputs, the model can be run forward to create a training set where the outputs become the inputs. If there are cases where output may be duplicated for 2 or more different inputs, we have two options for inverting the model: (1) Identify duplicates, score them and eliminate all but best output; and (2)»Introduce an attribute to the output layer that categorizes each one of the duplicates appropriately.

The following examples pertain to further embodiments, from which numerous permutations and configurations will be apparent.

Example 1 includes [Examples will be added when claims are finalized]

It is emphasized that the Abstract of the Disclosure is provided to allow a reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. A method, comprising:
receiving setting parameters for an ion implanter, the setting parameters comprising a set of control parameters corresponding to a set of process parameters for the ion implanter;
predicting a preventative maintenance (PM) recovery time for a PM recovery phase of the ion implanter based on the setting parameters, the PM recovery time representing a time interval between a start time of the PM recovery phase and an end time of the PM recovery phase, using a machine learning model; and
presenting the recovery time on a graphical user interface (GUI) of an electronic device.

2. The method of claim 1, wherein the machine learning model is a variance model comprising an artificial neural network (ANN), where layers of the ANN are trained using output from a stress model.

3. The method of claim 1, wherein the machine learning model is a control model comprising an artificial neural network (ANN) trained using a first set of training data and re-trained as a variance model using a second set of training data, the first set of training data comprising setting parameters and the second set of training data comprising PM recovery data.

4. The method of claim 1, wherein the machine learning model is an artificial neural network (ANN) comprising an input layer, an output layer, and multiple hidden layers, the ANN trained by locking the multiple hidden layers and re-training the input layer and the output layer using PM recovery data, calibration data, or stress data.

5. The method of claim 1, comprising predicting a start time for a next PM recovery phase of the ion implanter using the machine learning model.

6. The method of claim 1, comprising:
predicting the set of process parameters for the ion implanter from the set of control parameters using the machine learning model, wherein the machine learning model is a variance model adapted from a control model using transfer learning;
determining a statistical process control (SPC) limit delta between the predicted process parameters and actual process parameters measured for the ion implanter;
comparing the SPC limit delta to a defined threshold value to obtain a comparison result; and
determining the end time of the PM recovery phase based on comparison result.

7. The method of claim 1, wherein the control parameter corresponds to a hardware or software setting that controls a configuration or operation of a component of the ion implanter, the at least one control parameter comprising a charge parameter, an energy parameter, an acceleration or deceleration parameter, a dopant and flow parameter, a diluent and flow parameter, a source parameter, an analyzer parameter, a corrector parameter, a suppression parameter, a focus parameter, a scan parameter, a quadrupole lens current parameter, or a post-acceleration voltage parameter.

8. The method of claim 1, wherein the process parameter corresponds to a metric associated with a beam property for an ion beam generated by the ion implanter, the at least one process parameter comprising a beam height parameter, a beam width parameter, full half height maximum (FHHM) parameter, a vertical within device angle (VWIDA) parameter, a VWIDA mean (VWIDAM) parameter, a horizontal within device angle (HWIDA) parameter, a HWIDA mean (HWIDAM) parameter, a standard deviation of VWIDA (VWIDAS) parameter, a standard deviation of HWIDA mean (HWIDAS) parameter, a vertical intensity (VI) parameter, a spotscore parameter, an energy parameter, a region of interest (ROI) current parameter, or a uniformity parameter.

9. The method of claim 1, comprising generating instructions to indicate the ion implanter has reached an end time of the PM recovery phase and is ready to enter an operational phase to generate an ion beam for implanting ions in a semiconductor wafer.

10. A non-transitory computer-readable storage medium, the computer-readable storage medium including instructions that when executed by a computer, cause the computer to:
receive setting parameters for an ion implanter, the setting parameters comprising a set of control parameters corresponding to a set of process parameters for the ion implanter;
predict a preventative maintenance (PM) recovery time for a PM recovery phase of the ion implanter based on the setting parameters, the PM recovery time representing a time interval between a start time of the PM recovery phase and an end time of the PM recovery phase, using a machine learning model; and
present the recovery time on a graphical user interface (GUI) of an electronic device.

11. The computer-readable storage medium of claim 10, wherein the machine learn model is a variance model comprising an artificial neural network (ANN), where layers of the ANN are trained using output from a stress model.

12. The computer-readable storage medium of claim 10, wherein the machine learn model is a control model comprising an artificial neural network (ANN) trained using a first set of training data and re-trained as a variance model using a second set of training data, the first set of training data comprising setting parameters and the second set of training data comprising PM recovery data.

13. The computer-readable storage medium of claim 10, wherein the machine learn model is an artificial neural network (ANN) comprising an input layer, an output layer, and multiple hidden layers, the ANN trained by locking the multiple hidden layers and re-training the input layer and the output layer using PM recovery data, calibration data, or stress data.

14. The computer-readable storage medium of claim 10, comprising instructions that when executed by a computer, cause the computer to predict a start time for a next PM recovery phase of the ion implanter using the machine learning model.

15. The computer-readable storage medium of claim 10, comprising instructions that when executed by a computer, cause the computer to:
predict the set of process parameters for the ion implanter from the set of control parameters using the machine learning model, wherein the machine learning model is a variance model adapted from a control model using transfer learning;
determine a statistical process control (SPC) limit delta between the predicted process parameters and actual process parameters measured for the ion implanter;
compare the SPC limit delta to a defined threshold value to obtain a comparison result; and
determine the end time of the PM recovery phase based on comparison result.

16. The computer-readable storage medium of claim 10, comprising instructions that when executed by a computer, cause the computer to generate a message to indicate the ion implanter has reached an end time of the PM recovery phase and is ready to enter an operational phase to generate an ion beam for implanting ions in a semiconductor wafer.

17. An ion implanter, comprising:
an ion source to generate an ion beam;
at least one beamline component to direct the ion beam towards a substrate;
a processing circuitry; and
a memory coupled to the processing circuitry, the memory storing instructions that, when executed by the processor circuitry, configure the processing circuitry to:
receive setting parameters for an ion implanter, the setting parameters comprising a set of control parameters corresponding to a set of process parameters for the ion implanter;
predict a preventative maintenance (PM) recovery time for a PM recovery phase of the ion implanter based on the setting parameters, the PM recovery time representing a time interval between a start time of the PM recovery phase and an end time of the PM recovery phase, using a machine learning model; and
present the recovery time on a graphical user interface (GUI) of an electronic device.

18. The ion implanter of claim 10, the processing circuitry to predict a start time for a next PM recovery phase of the ion implanter using the machine learning model.

19. The ion implanter of claim 10, the processing circuitry to:
predict the set of process parameters for the ion implanter from the set of control parameters using the machine learning model, wherein the machine learning model is a variance model adapted from a control model using transfer learning;
determine a statistical process control (SPC) limit delta between the predicted process parameters and actual process parameters measured for the ion implanter;
compare the SPC limit delta to a defined threshold value to obtain a comparison result; and
determine the end time of the PM recovery phase based on comparison result.

20. The ion implanter of claim 10, the processing circuitry to generate a control directive to indicate the ion implanter has reached an end time of the PM recovery phase and is ready to enter an operational phase to generate an ion beam for implanting ions in a semiconductor wafer.
